(19) United States
(12) Patent Application Publication
(10) Pub. No.: US 2025/0098400 A1
(43) Pub. Date: Mar. 20, 2025

(54) LIGHT-EMITTING DEVICE, DISPLAY PANEL AND DISPLAY APPARATUS

(71) Applicant: BOE TECHNOLOGY GROUP CO., LTD., Beijing (CN)

(72) Inventors: Haiyan SUN, Beijing (CN); Xiaojin ZHANG, Beijing (CN); Dan WANG, Beijing (CN)

(73) Assignee: BOE TECHNOLOGY GROUP CO., LTD., Beijing (CN)

(21) Appl. No.: 18/576,367

(22) PCT Filed: May 17, 2023
(86) PCT No.: PCT/CN2023/094811

§ 371 Date: Jan. 4, 2024

(51) Int. Cl. H10K 50/125; H10K 50/12; H10K 85/30; H10K 101/00; H10K 101/10; H10K 101/40

(52) U.S. Cl. CPC H10K 50/125; H10K 50/12; H10K 85/346; H10K 2101/10; H10K 2101/40; H10K 2101/90

(57) ABSTRACT

A light-emitting device is provided, and the light-emitting device includes a first electrode, a second electrode and at least two light-emitting units. The first electrode and the second electrode are arranged in a first direction in sequence. The at least two light-emitting units are disposed between the first electrode and the second electrode, and are arranged in a second direction, and the second direction intersects the first direction. Photons emitted by each light-emitting unit of the at least two light-emitting units include first luminescent photons and second luminescent photons. Emission time of the first luminescent photons is less than emission time of the second luminescent photons. The number of second luminescent photons emitted by at least one light-emitting unit is less than or equal to the number of first luminescent photons emitted by the at least one light-emitting unit.

### CROSS-REFERENCE TO RELATED APPLICATION

The present application is a national phase entry under 35 USC 371 of International Patent Application No. PCT/CN2023/094811, filed on May 17, 2023, which is incorporated herein by reference in its entirety.

### TECHNICAL FIELD

The present disclosure relates to the field of display technologies, and in particular, to a light-emitting device, a display panel and a display apparatus.

### BACKGROUND

Organic light-emitting diode (OLED) display apparatuses have advantages of self-illumination, high color gamut, high saturation and high response speed, and are widely used in display screens such as mobile phones, tablets, and car displays.

### SUMMARY

In an aspect, a light-emitting device is provided. The light-emitting device includes a first electrode, a second electrode and at least two light-emitting units. The first electrode and the second electrode are arranged in a first direction in sequence. The at least two light-emitting units are disposed between the first electrode and the second electrode, and are arranged in a second direction, and the second direction intersects the first direction. Photons emitted by each light-emitting unit of the at least two light-emitting units include first luminescent photons and second luminescent photons. Emission time of the first luminescent photons is less than emission time of the second luminescent photons. The number of second luminescent photons emitted by at least one light-emitting unit is less than or equal to the number of first luminescent photons emitted by the at least one light-emitting unit.

In some embodiments, the at least two light-emitting units include at least three light-emitting units, and the at least three light-emitting units are arranged in the second direction. Under a normalization condition, for any two light-emitting units, a difference of a ratio of the number of first luminescent photons to the number of photons emitted by a light-emitting unit is less than or equal to 40%.

In some embodiments, each light-emitting unit of the at least two light-emitting units includes at least one light-emitting layer. Each light-emitting layer of the at least one light-emitting layer includes a first host material and a luminescent material, and the at least one light-emitting layer further includes a second host material. Triplet energy level of the second host material is less than or equal to triplet energy level of the first host material, and the triplet energy level of the second host material is greater than or equal to triplet energy level of the luminescent material.

In some embodiments, a difference between the triplet energy level of the first host material and the triplet energy level of the second host material is greater than or equal to 0.1 eV, and a difference between the triplet energy level of the second host material and the triplet energy level of the luminescent material is greater than or equal to 0.1 eV.

In some embodiments, a difference between a peak wavelength of an emission spectrum of the second host material and a peak wavelength of an absorption spectrum of the luminescent material is less than or equal to 40 nm.

In some embodiments, a difference between a peak wavelength of an emission spectrum of the second host material and a peak wavelength of an absorption spectrum of the luminescent material is less than or equal to 30 nm.

In some embodiments, singlet energy level of the first host material is greater than or equal to singlet energy level of the second host material, and the singlet energy level of the second host material is greater than or equal to singlet energy level of the luminescent material.

In some embodiments, an absolute value of a difference between a highest occupied molecular orbital energy level of the second host material and a highest occupied molecular orbital energy level of the first host material is less than or equal to 0.3 eV. An absolute value of a difference between a lowest occupied molecular orbital energy level of the second host material and a lowest occupied molecular orbital energy level of the luminescent material is less than or equal to 0.2 eV. An absolute value of the lowest occupied molecular orbital energy level of the second host material is greater than or equal to an absolute value of a lowest occupied molecular orbital energy level of the first host material. An absolute value of a lowest occupied molecular orbital energy level of the luminescent material is greater than or equal to the absolute value of the lowest occupied molecular orbital energy level of the first host material.

In some embodiments, in each light-emitting layer, the difference between the triplet energy level of the first host material and the triplet energy level of the luminescent material is greater than or equal to 0.15 eV.

In some embodiments, the second host material includes any one of ligand groups IA represented by a general formula I.

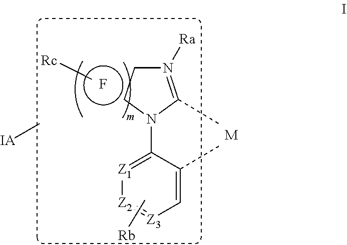

F is selected from a five-membered or six-membered carbocyclic ring or carboheterocyclic ring; a value of m is selected from any one of 0, 1, 2, 3 and 4; Z and Z₃ are the same or different, and are each independently selected from carbon and nitrogen the ligand group IA is bonded to M, and M is selected from any one of ruthenium, osmium, iridium, palladium, copper, silver and gold; the second host material includes n-dentate ligand material formed by the structure shown by the general formula I and M, and a value of n is selected from any one of 3, 4, 5 and 6; and Pa, Rb and Rc are the same or different, and are independently selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether-, ester, nitrile, isonitrile, sulfenyl, sulfinyl, sulfonyl, and phosphine.

In some embodiments, the second host material is selected from any one of structures represented by the following general formula II

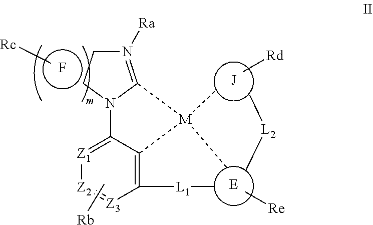

F is selected from a five-membered or six-membered carbocyclic ring or carboheterocyclic ring; a value of m is selected from any one of 0, 1, 2, 3 and 4; J and E are the same or different, and are independently selected from a five-membered or six-membered carbocyclic ring or carboheterocyclic ring; Z₁, Z₂ and Z₃ are the same or different, and are each independently selected from carbon and nitrogen; M is selected from one of platinum and palladium; L₁ and L₂ are the same or different, and are independently selected from any of B(Rf), N(Rf), P(Rf), O, S, Se, C═O, S═O, SO₂, C(Rf Rg), Si(Rf Rg) and Ge(Rf Rg); and Ra, Rb, Rc, Re, Rd, Rf, and Rg are the same or different, and are independently selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphine.

In yet some embodiments, J and E are not both the five-membered carbocyclic ring or carboheterocyclic ring.

In yet some other embodiments, L₁ and L₂ are different.

In yet some other embodiments, at least one of Ra, Rb, and Rc contains deuterium.

In yet some other embodiments, a mass proportion of the second host material in the light-emitting layer is greater than or equal to 10% and less than or equal to 50%.

In some embodiments, the second host material is selected from any one of structures represented by the following general formula III.

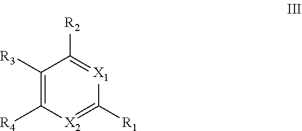

X₁ and X₂ are the same or different, and are independently selected from carbon and nitrogen; R₁, R₂, R₃ and R₄ are the same or different, and are independently selected from one of a substituted or unsubstituted substituent group IIIA and a substituted or unsubstituted substituent group IIIB; R₁, R₂, R₃ and R₄ contains at least two substituted or unsubstituted substituent groups IIIA and at least one substituted or unsubstituted substituent group IIIB; the substituent group IIIA is selected from any one of IIIA-a to IIIA-i.

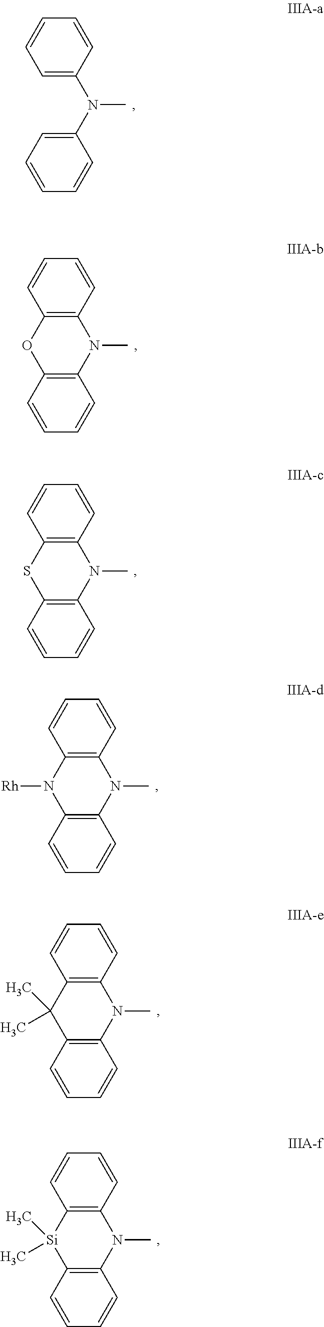

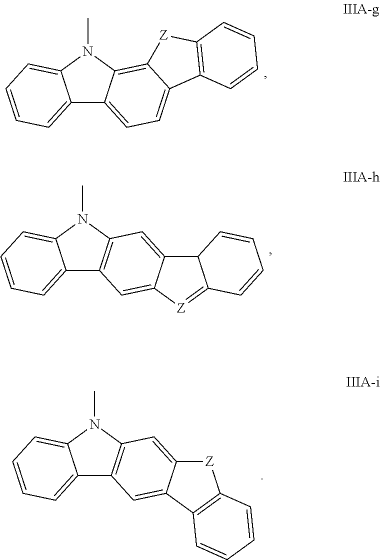

Z is selected from any one of carbon, nitrogen, oxygen and sulfur; Rh is selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphine.

The substituent group IIIB is selected from any one of IIIB-a to IIIB-j.

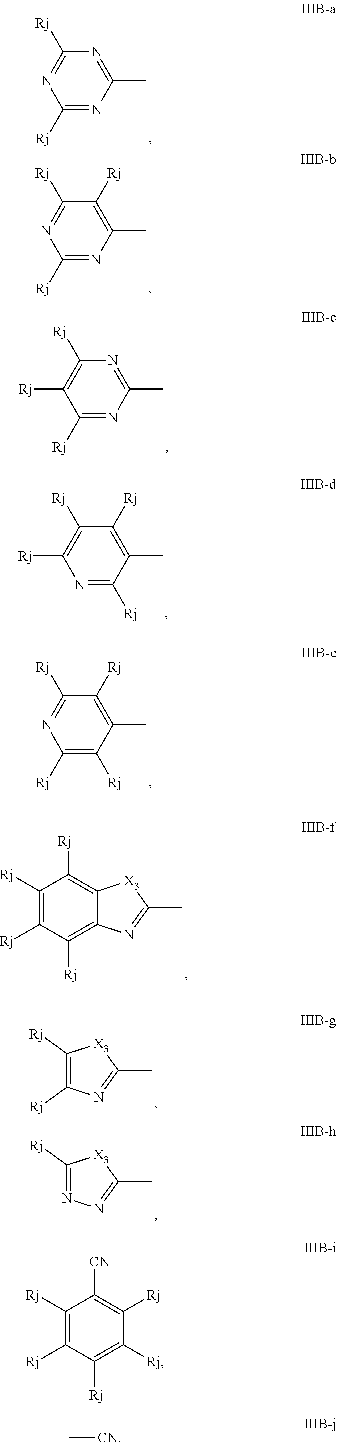

X₃ is selected from oxygen and sulfur; Rj is selected from any one of hydrogen, deuterium, halogen, nitrile, substituted or unsubstituted alkyl, substituted or unsubstituted haloalkyl, substituted or unsubstituted alkoxy, substituted or unsubstituted haloalkoxy, substituted or unsubstituted aryl, substituted or unsubstituted haloaryl group, substituted or unsubstituted silyl group, and substituted or unsubstituted heterocycle.

In yet some other embodiments, a mass proportion of the second host material in the light-emitting layer is greater than or equal to 20% and less than or equal to 55%.

In yet some other embodiments, a mass proportion of the second host material in the light-emitting layer is less than or equal to a mass proportion of the first host material in the light-emitting layer.

In yet some other embodiments, a light-emitting unit includes a plurality of light-emitting layers, and the plurality of light-emitting layers are stacked in the first direction.

In another aspect, a display panel is provided. The display panel includes the light-emitting device as described in any of the above embodiments and a driving circuit. The driving circuit is used to drive the light-emitting device to emit light.

In yet another aspect, a display apparatus is provided. The display apparatus includes the display panel as described in any of the above embodiments and a driver chip. The driver chip is used to drive the display panel to perform display.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments of the present disclosure;

FIG. 2 is a structural diagram of a display panel, in accordance with some embodiments of the present disclosure;

FIG. 3 is a structural diagram of a light-emitting device, in accordance with some embodiments of the present disclosure;

FIG. 4 is a structural diagram of another light-emitting device, in accordance with some embodiments of the present disclosure;

FIG. 5 is a structural diagram of yet another light-emitting device, in accordance with some embodiments of the present disclosure:

FIG. 6 is a transient decay curve of a light-emitting device, in accordance with some embodiments of the present disclosure;

FIG. 7 is a transient decay curve of another light-emitting device, in accordance with some embodiments of the present disclosure;

FIG. 8 is a transient decay curve of yet another light-emitting device, in accordance with some embodiments of the present disclosure:

FIG. 9 is a transient decay curve of yet another light-emitting device, in accordance with some embodiments of the present disclosure; and

FIG. 10 is a transient decay curve of yet another light-emitting device, in accordance with some embodiments of the present disclosure.

### DETAILED DESCRIPTION

The technical solutions in some embodiments of the present disclosure will be described clearly and completely with reference to the accompanying drawings; however, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating a number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term such as “about”, “substantially”, and “approximately” as used herein includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views that are schematic illustrations of idealized embodiments. In the accompanying drawings, thicknesses of layers and areas of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in a device, and are not intended to limit the scope of the exemplary embodiments.

It will be noted that, for example, “11˜1” shown in the drawings of the present disclosure indicates that the component 11 belongs to the component 1, and “131˜130”, for example, indicates that the light-emitting layer 131 belongs to the light-emitting unit 130. Other similar reference signs shown in the drawings also follow the above description.

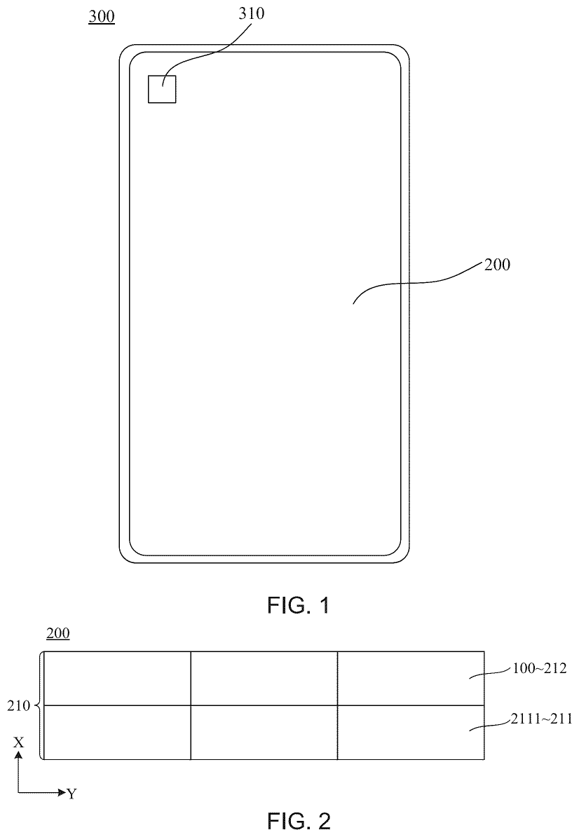

As shown in FIG. 1, some embodiments of the present disclosure provide a display apparatus 300, and the display apparatus 300 includes a display panel 200.

In some examples, the display apparatus 300 may be an organic light-emitting diode (OLED) display apparatus.

For example, as shown in FIG. 1, the display apparatus 300 further includes a driver chip 310. The driver chip 310 is used to drive the display panel 200 to perform display.

In addition, the display apparatus 300 may further include an under-screen camera, an under-screen fingerprint recognition sensor and the like, so that the display apparatus 300 is able to implement various functions such as taking pictures, video recording, fingerprint recognition, or face recognition.

The display apparatus 300 may be any display apparatus 300 that displays an image whether in motion (e.g., a video) or stationary (e.g., a still image), and whether literal or graphical. More specifically, it is expected that the display apparatus 300 in the embodiments may be implemented in or associated with a plurality of electronic devices. The plurality of electronic devices may include (but is not limit to), for example, mobile telephones, wireless devices, personal data assistants (PAD), hand-held or portable computers, GPS receivers/navigators, cameras, MP4 video players, video cameras, game consoles, watches, clocks, calculators, TV monitors, flat panel displays, computer monitors, car displays (e.g., odometer displays), navigators, cockpit controllers and/or displays, camera view displays (e.g., rear view camera displays in vehicles), electronic photos, electronic billboards or indicators, projectors, building structures, packagings and aesthetic structures (e.g., a display for an image of a piece of jewelry).

In some embodiments, referring to FIG. 2, the display panel 200 includes a display substrate 210. The display substrate 210 includes an array layer 211 and a light-emitting functional layer 212. The light-emitting functional layer 212 is located on a side of the array layer 211. The array substrate includes a plurality of driving circuit 2111. The light-emitting functional layer 212 includes a plurality of light-emitting devices 100.

In some examples, referring to FIG. 2, the plurality of driving circuits 2111 are coupled to the plurality of light-emitting devices 100 in one-to-one correspondence. In some other examples, a driving circuit 2111 is coupled to multiple light-emitting devices 100, or multiple driving circuits 2111 are coupled to a light-emitting device 100.

For example, in the display panel 200, the driving circuit 2111 generates a driving current. Each light-emitting device 100 emits light due to the driving action of the driving current generated by the corresponding driving circuit(s) 2111, and the light emitted by all the light-emitting devices 100 cooperates with each other, so that the display panel 200 realizes the display function.

In some implementations, when the OLED display apparatus displays a certain picture for a long time and then switches, problems such as slight smearing or image retention occurs.

In some other implementations, the display image of the OLED display apparatus is formed by mixing red (R), green (G) and blue (B) colors, and the response speeds of the three RGB colors are different. In a case where the response speed difference between the three RGB colors is large, the smearing or afterimage of the display image will be aggravated.

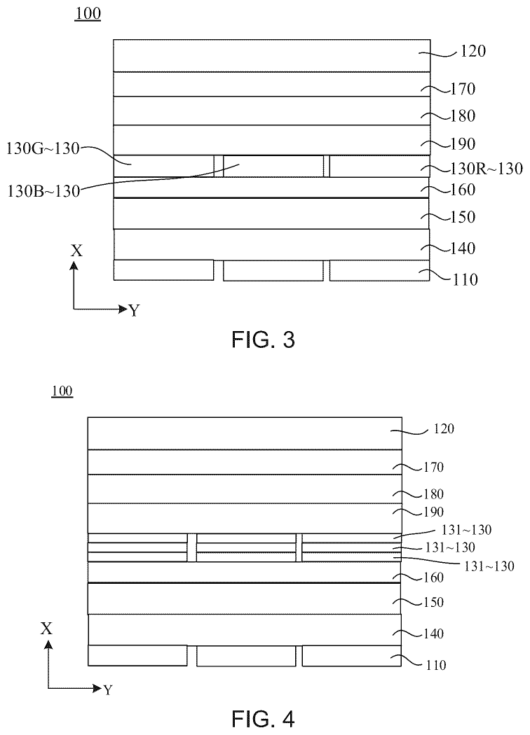

Based on this, referring to FIG. 3, some embodiments of the present disclosure provide a light-emitting device 100, and the light-emitting device 100 includes a first electrode 110, a second electrode 120, and at least two light-emitting units 130. The first electrode 110 and the second electrode 120 are arranged in a first direction X in sequence. The at least two light-emitting units 130 are disposed between the first electrode 110 and the second electrode 120, and are arranged in a second direction Y, and the second direction Y intersects the first direction X. Photons emitted by each light-emitting unit 130 of the at least two light-emitting units 130 include first luminescent photons and second luminescent photons. Emission time of the first luminescent photons is less than emission time of the second luminescent photons. The number of second luminescent photons emitted by at least one light-emitting unit 130 is less than or equal to the number of first luminescent photons emitted by the at least one light-emitting unit 130.

In some examples, referring to FIG. 3, the second direction Y is perpendicular to the first direction X. The first electrode 110 may be an anode, and the second electrode 120 may be a cathode. During operation, voltages are applied to the first electrode 110 and the second electrode 120 respectively to generate an electric field therebetween, which can drive holes in the anode and electrons in the cathode to recombine in the light-emitting unit 130, thereby emitting light. The emission light includes light emitted by the first luminescent photons and light emitted by the second luminescent photons.

For example, in order to ensure that the light-emitting device 100 can effectively emit light, the first electrode 110 (anode) is made of a material with a high work function, such as a material with a work function greater than 6 eV; the second electrode 120 (cathode) is made of a material with a low work function, such as a material with a work function smaller than a set value, and the set value is in a range of 2.0 eV to 3.0 eV, inclusive, so that the holes in the anode and the electrons in the cathode can effectively migrate to the light-emitting unit 130 under the driving of the electric field to recombine to emit light.

In some examples, the light-emitting device 100 is a bottom-emission light-emitting device, and the material of the first electrode 110 may be a transparent conductive metal oxide material, so as to prevent the first electrode 110 from blocking light. For example, the material of the first electrode 110 is indium tin oxide (ITO) or indium zinc oxide (IZO); the thickness of the first electrode 110 may be in a range of 80 nm to 200 nm, inclusive. The average reflectivity of the material of the first electrode 110 in the visible light range may be in a range of 85% to 95%, inclusive. The material of the second electrode 120 may be a metal material. For example, the material of the second electrode 120 is magnesium, silver, aluminum, or magnesium-silver alloy. In a case where the material of the second electrode 120 is magnesium-silver alloy, a mass ratio of magnesium to silver is in a range of 3:7 to 1:9, inclusive. The process of forming the second electrode 120 is, for example, evaporation. The thickness of the second electrode 120 may be greater than or equal to 80 nm, so as to ensure the good reflectivity.

In some other examples, the light-emitting device 100 is a top-emission light-emitting device, and the first electrode 110 may be made of a composite layer structure composed of metal/conductive metal oxide. For example, the first electrode 110 is made of silver/indium tin oxide composite layer structure, or silver/indium zinc oxide composite layer structure, in which a thickness of the metal layer may be in a range of 80 nm to 100 nm, inclusive, and a thickness of the conductive metal oxide may be in a range of 5 nm to 10 nm, inclusive. The average reflectivity of the material of the first electrode 110 in the visible light range may be in a range of 85% to 95%, inclusive. The material of the second electrode 120 may be a metal material. For example, the material of the second electrode 120 is magnesium, silver, aluminum, or magnesium-silver alloy. In a case where the material of the second electrode 120 is magnesium-silver alloy, a mass ratio of magnesium to silver is in a range of 3:7 to 1:9, inclusive. The process of forming the second electrode 120 is, for example, evaporation. The thickness of the second electrode 120 may be in a range of 10 nm to 20 nm, inclusive. The transmittance of the material of the second electrode 120 is in a range of 50% to 60%, inclusive, at 530 nm.

In some embodiments, referring to FIG. 3, in order to improve the luminous efficiency of the light-emitting device 100, at least one of a hole injection layer 140 (HIL), a hole transport layer 150 (HTL), and electron blocking layer 160 (EBL) is provided between the first electrode 110 and the light-emitting units 130; at least one of an electron injection layer 170 (EIL), an electron transport layer 180 (ETL), and a hole blocking layer 190 (EBL) is provided between the second electrode 120 and the light-emitting units 130. By arranging the hole injection layer 140, the hole transport layer 150, the electron blocking layer 160, the electron injection layer 170, the electron transport layer 180, and the hole blocking layer 190, it is equivalent to provide a transitional step between the anode and the light-emitting units 130, and between the cathode and the light-emitting units 130, which reduces the barrier height that carrier transition needs to overcome, so that the luminous efficiency is improved.

For example, the hole injection layer 140 is configured to reduce the hole injection barrier to improve the hole injection efficiency; the hole injection layer 140 may be a single layer film formed of a single material, and the material of the hole injection layer 140 is, for example, 1,4,5,8,9,11-hexaazatriphenylenehexacarbonitrile (HAT-CN), or Copper(II) phthalocyanine (CuPc). The hole injection layer 140 may also be formed by performing P-type doping on the hole transport material; for example, N,N′-bis(naphthalen-1-yl)-N,N′-bis(phenyl)benzidine (NPB) is doped with 2,3,5,6-Tetrafluoro-7,7,8,8-tetracyanoquinodimethane (F4-TCNQ), or 1,1-bis[4-[N,N′-di(p-tolyl)amino]phenyl]cyclohexane (TAPC) is doped with trioxide manganese (MnO₃), and the doping concentration may be in a range of 0.5% to 10%, inclusive. The thickness of the hole injection layer 140 may be in a range of 5 nm to 20 nm, inclusive.

For example, the hole transport layer 150 is configured to transport holes, and the material of the hole transport layer 150 may be a material with a high hole mobility, such as a carbazole-based material. The forming process of the hole transport layer 150 may be evaporation. A highest occupied molecular orbital (HOMO) energy level of the hole transport layer 150 may be in a range of 5.2 eV to 5.6 eV, inclusive. The thickness of the hole transport layer 150 may be in a range of 100 nm to 140 nm, inclusive.

For example, the electron blocking layer 160 is configured to block electrons and excitons generated in the light emitting unit 130; the thickness of the electron blocking layer 160 may be in a range of 1 nm to 10 nm, inclusive.

For example, the thickness of the electron injection layer 170 is in a range of 0.5 nm to 2 nm, inclusive.

For example, the thickness of the electron transport layer 180 is in a range of 20 nm to 70 nm, inclusive.

For example, the hole blocking layer 190 is configured to block holes and excitons generated in the electron transport layer 180; the thickness of the hole blocking layer 190 may be in a range of 2 nm to 10 nm, inclusive.

In some embodiments, referring to FIG. 3, the second electrode 120 stacked with all the light-emitting units 130 is of a whole-layer structure; that is, the second electrode 120 may be a common electrode shared by the plurality of light-emitting units 130. The hole injection layer 140 stacked with all the light-emitting unit 130 may also be of a whole-layer structure; that is, the hole injection layer 140 may be a common film layer shared by the plurality of light-emitting units 130. The hole transport layer 150, the electron blocking layer 160, the hole blocking layer 190, the electron injection layer 170, and the electron transport layer 180 may each also be a common film layer shared by the plurality of light-emitting units 130.

Photons emitted by each light-emitting unit 130 of the at least two light-emitting units 130 include first luminescent photons and second luminescent photons, and the emission time of the first luminescent photons is less than the emission time of the second luminescent photons. It will be understood that the light-emitting unit 130 is a structure in the light-emitting device 100 that implements the function of emitting light. The process of emitting light by the light-emitting unit 130 is completed within a light-emitting period, that is, each photon emitted by the light-emitting unit 130 corresponds to a different emission time. Thus, among the photons emitted by the light-emitting unit 130, some photons are emitted relatively early, i.e., instantaneously emitted, and some photons are emitted relatively late, i.e., delayed emitted; the first light-emitting photons are photons emitted by the luminous unit 130 relatively early, i.e., the first luminous photons are the instantaneous luminous component of the photons emitted by the light-emitting unit 130; the second light-emitting photons are the photon emitted by the light-emitting unit 130 relatively late, i.e., the second light-emitting photons are the delayed luminescence component of the photons emitted by the light-emitting unit 130. For example, the first luminescent photons are photons whose emission time is less than 1 ρs, and the second luminescence photons are photons whose emission time is greater than or equal to 1 μs. It will be noted that the term “emission time” refers to the time elapsed from removal of the driving voltage to photon emission.

It will be understood that in the at least two light-emitting units 130, in a case where the number of the second luminescence photons of at least one light-emitting unit 130 is less than or equal to the number of the first luminescence photons of at least one light-emitting unit 130, a ratio E2 of the number of the second luminescence photons to the number of photons emitted by the light-emitting unit 130 is less than or equal to a ratio E1 of the number of first luminescence photons to the number of the photons emitted by the light-emitting unit 130, i.e., E2≤E1. In this way, more photons can be emitted quickly due to the action of the driving voltage, which improves the response speed of the light-emitting unit 130. In a case where a certain screen is displayed for a long time and then switched, the tailing and afterimage phenomena of the display screen are effectively eliminated.

For example, the ratio E1 of the number of the first luminescent photons to the number of the photons emitted by the light-emitting unit 130 and the ratio E2 of the number of the second luminescent photons to the number of the photons emitted by the light-emitting unit 130 are calculated by fitting the transient decay curve. The transient decay curve may be measured using a transient spectrometer. During measurement, a square wave signal not lower than the driving voltage is input to the light-emitting device 100. The transient spectrometer is, for example, a transient fluorescence spectrometer of model FLS1000; the voltage value of the driving voltage is, for example, 3V.

In some embodiments, the at least two light-emitting units 130 include at least three light-emitting units 130, and the at least three light-emitting units 130 are arranged in the second direction Y. Under a normalization condition, for any two light-emitting units 130, a difference of a ratio of the number of first luminescent photons to the number of photons emitted by the light-emitting unit 130 is less than or equal to 40%.

For example, referring to FIGS. 2 and 3, the at least two light-emitting units 130 include three light-emitting units 130; for example, the three light-emitting units 130 are respectively a red light-emitting unit 130R, a green light-emitting unit 130G, and a blue light-emitting unit 130B. The red light-emitting unit 130R emits red light, the green light-emitting unit 130G emits green light, and the blue light-emitting unit 130B emits blue light. The three light-emitting units 130 are arranged in the second direction Y, and the second direction Y is perpendicular to the first direction X. By arranging three light-emitting units 130, it is possible to respectively adjust the luminance (gray scale) of the light-emitting units 130 of different colors, and multiple colors can be displayed through color combination and superposition, so that full-color display of the display panel 200 is achieved.

In some other embodiments, the at least two light-emitting units 130 include M light-emitting units 130, where M is a positive integer greater than three; the M light-emitting units 130 are arranged in the second direction Y, and the second direction Y is perpendicular to the first direction X. For example, the number of red light-emitting units 130R is at least two, and/or the number of green light-emitting units 130G is at least two, and/or the number of blue light-emitting units 130B is at least two.

It will be noted that the normalization condition refers to normalizing the number of photons emitted by the light-emitting unit 130 to 1. Under the normalization condition, the number of the first luminescent photons is the ratio of the number of the first luminescent photons to the number of photons emitted by the light-emitting unit 130, and the number of the second luminescent photons is the ratio of the number of the second luminescent photons to the number of photons emitted by the light-emitting unit 130.

It will be noted that, considering the green light-emitting unit 130G and the red light-emitting unit 130R as an example, for these two light-emitting units 130, the difference of the ratio of the number of first luminescent photons and the number of photons emitted by the light-emitting unit 130 means that, in the green light-emitting unit 130G, the number of the first luminescent photons is G1, and the number of the second luminescent photons is G2; in the red light-emitting unit 130R, the number of the first luminescent photons is R1, and the number of the second luminescent photons is R2; then for the green light-emitting unit 130G and the red light-emitting unit 130R, the difference ΔGR between the number of first luminescent photons and the number of photons emitted by the light-emitting unit 130 is as follows.

$$Δ G R = \vert \frac{G 1}{G 1 + G 2} \times 100 \% - \frac{R 1}{R 1 + R 2} \times 100 \% \vert \qquad ( 1 )$$

In a case where the at least two light-emitting units 130 include three light-emitting units 130, i.e., a red light-emitting unit 130R, a green light-emitting unit 130G, and a blue light-emitting unit 130B, for any two light-emitting units 130, the difference of the ratio of the number of first luminescent photons to the number of photons emitted by 130 is less than or equal to 40%, which means that the light-emitting device 100 satisfies:

ΔGR≤40%;ΔBR≤40%; and ΔBG≤40%.

As for the difference ΔBR between the ratio of the number of first luminescent photons to the number of photons emitted by the light-emitting unit 130 for the blue light-emitting unit 130B and the red light-emitting unit 130R and the difference ΔBG between the ratio of the number of first luminescent photons to the number of photons emitted by the light-emitting unit 130 for the blue light-emitting unit 1308 and the green light-emitting unit 130G, reference is made to the above description of ΔGR, which will not be repeated here.

It can be understood that, by limiting the difference of the ratio of the number of first luminescent photons to the number of photons emitted by the light-emitting unit 130 for any two light-emitting units 130, it is possible to reduce the difference of the ratio of the number of first luminescent photons to the number of photons emitted by the light-emitting unit 130 for all light-emitting units 130, i.e., reduce the difference of the ratio of the number of second luminescent photons to the number of photons emitted by the light-emitting unit 130 for all light-emitting units 130, so that the proportion of delayed luminous component in the photons emitted by each luminous unit 130 tends to be consistent, and in turn the response speeds of each light-emitting unit 130 tend to be consistent. As a result, in a case where a certain screen is displayed for a long time and then switched, the tailing and afterimage phenomena of the display screen may be effectively alleviated.

Referring to FIG. 4, in some embodiments, each light-emitting unit 130 of the at least two light-emitting units 130 includes at least one light-emitting layer 131, and each light-emitting layer 131 of the at least one light-emitting layer 131 includes a first host material H1 and luminescent material D; the at least one light-emitting layer 131 further includes a second host material H2. Triplet energy level T1(H2) of the second host material H2 is less than or equal to triplet energy level T1(H1) of the first host material H1; triplet energy level T1(H2) of the second host material H2 is greater than or equal to triplet energy level T1(D) of the luminescent material D, i.e., T1(D)≤T1(H2)≤T1(H1).

It can be understood that the light-emitting layer 131 is the part of the light-emitting unit 130 that plays the luminescent function, and both the first luminescent photons and the second luminescent photons are emitted from the light-emitting layer 131.

The light-emitting layer 131 includes the first host material H1 and the luminescent material D. For example, the first host material H1 is configured to transmit energy, and the luminescent material D is configured to emit light.

For example, the structural formula of the first host material H1 is any one of H1-1 to H1-30 as shown below.

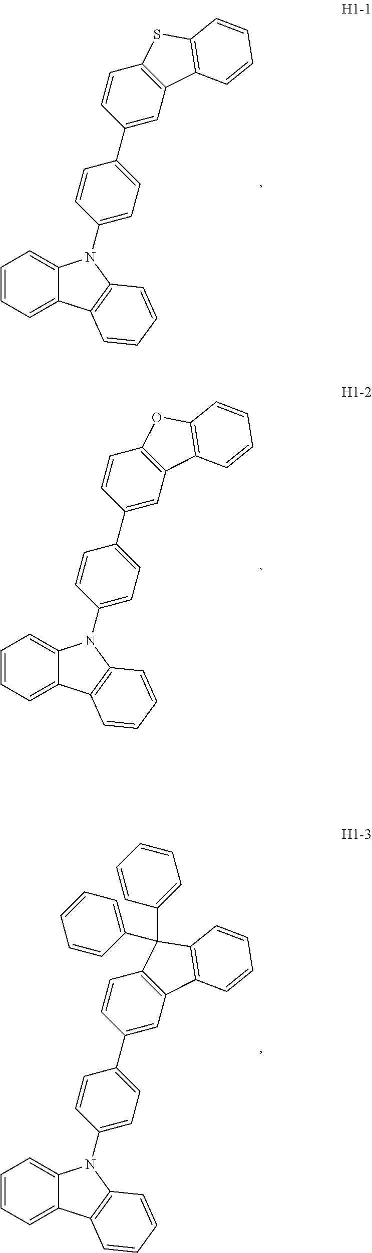 [SMILES: c1ccc2c(c1)sc1ccc(-c3ccc(-n4c5ccccc5c5ccccc54)cc3)cc12 ; c1ccc2c(c1)oc1ccc(-c3ccc(-n4c5ccccc5c5ccccc54)cc3)cc12 ; c1ccc(C2(c3ccccc3)c3ccccc3-c3cc(-c4ccc(-n5c6ccccc6c6ccccc65)cc4)ccc32)cc1]

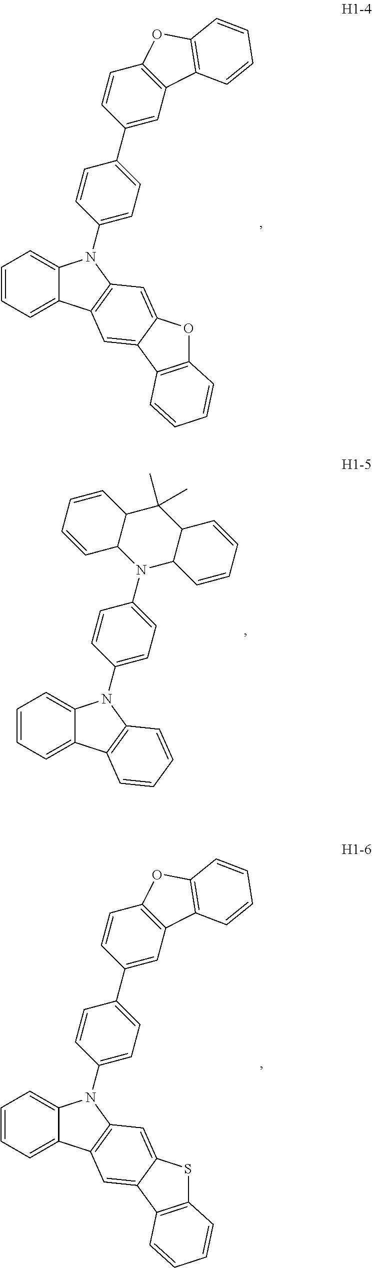 [SMILES: c1ccc2c(c1)oc1ccc(-c3ccc(-n4c5ccccc5c5cc6c(cc54)oc4ccccc46)cc3)cc12 ; CC1(C)C2C=CC=CC2N(c2ccc(-n3c4ccccc4c4ccccc43)cc2)C2C=CC=CC21 ; c1ccc2c(c1)oc1ccc(-c3ccc(-n4c5ccccc5c5cc6c(cc54)sc4ccccc46)cc3)cc12]

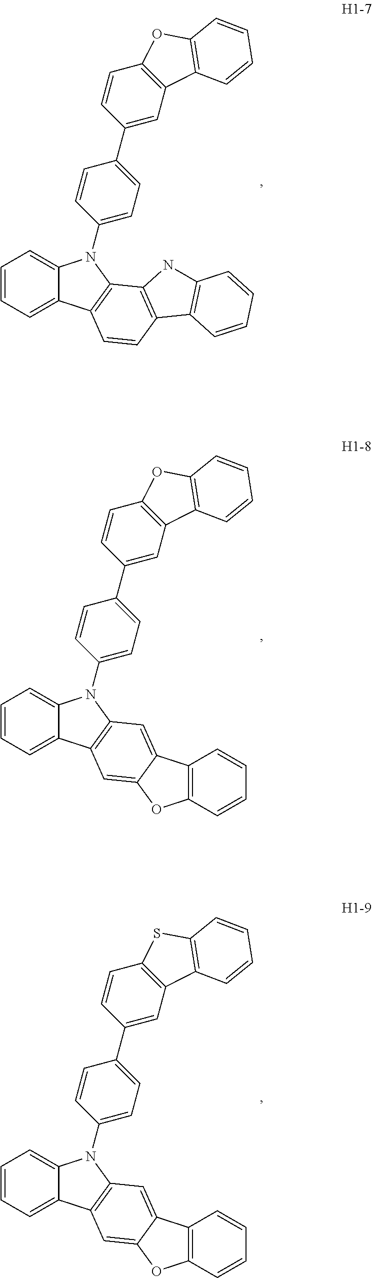 [SMILES: c1ccc2c(c1)[nH]c1c2ccc2c3ccccc3n(-c3ccc(-c4ccc5oc6ccccc6c5c4)cc3)c21 ; c1ccc2c(c1)oc1ccc(-c3ccc(-n4c5ccccc5c5cc6oc7ccccc7c6cc54)cc3)cc12 ; c1ccc2c(c1)oc1cc3c4ccccc4n(-c4ccc(-c5ccc6sc7ccccc7c6c5)cc4)c3cc12]

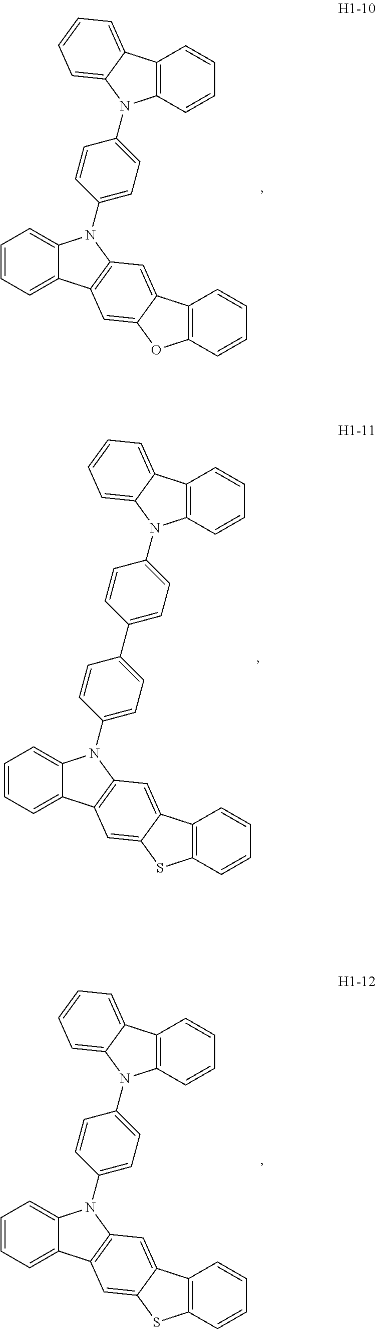 [SMILES: c1ccc2c(c1)oc1cc3c4ccccc4n(-c4ccc(-n5c6ccccc6c6ccccc65)cc4)c3cc12 ; c1ccc2c(c1)sc1cc3c4ccccc4n(-c4ccc(-c5ccc(-n6c7ccccc7c7ccccc76)cc5)cc4)c3cc12 ; c1ccc2c(c1)sc1cc3c4ccccc4n(-c4ccc(-n5c6ccccc6c6ccccc65)cc4)c3cc12]

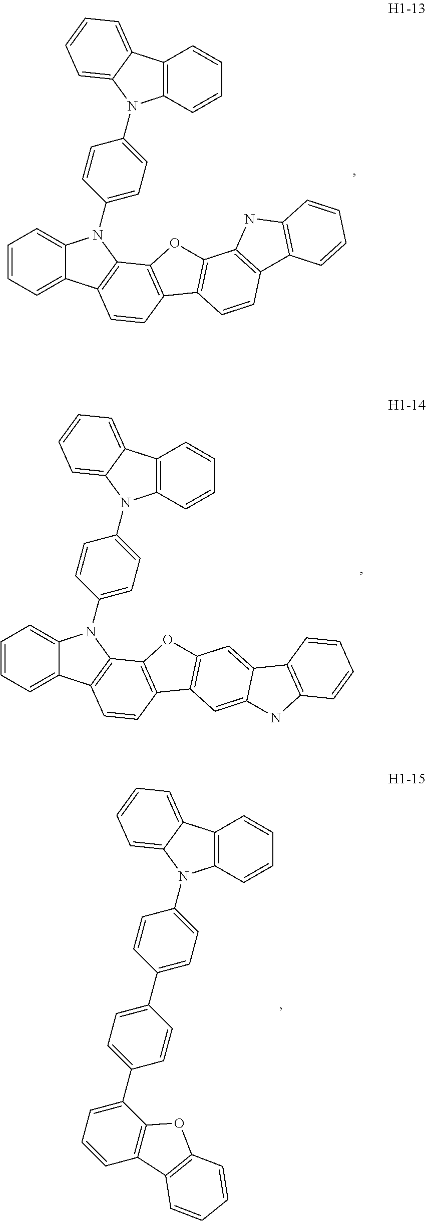 [SMILES: c1ccc2c(c1)[nH]c1c2ccc2c3ccc4c5ccccc5n(-c5ccc(-n6c7ccccc7c7ccccc76)cc5)c4c3oc21 ; c1ccc2c(c1)[nH]c1cc3c(cc12)oc1c3ccc2c3ccccc3n(-c3ccc(-n4c5ccccc5c5ccccc54)cc3)c21 ; c1ccc2c(c1)oc1c(-c3ccc(-c4ccc(-n5c6ccccc6c6ccccc65)cc4)cc3)cccc12]

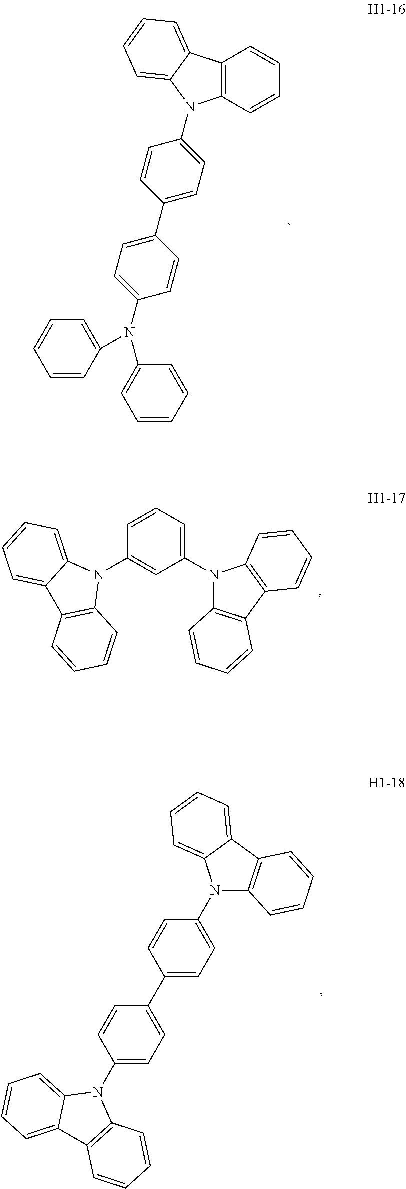 [SMILES: c1ccc(N(c2ccccc2)c2ccc(-c3ccc(-n4c5ccccc5c5ccccc54)cc3)cc2)cc1 ; c1cc(-n2c3ccccc3c3ccccc32)cc(-n2c3ccccc3c3ccccc32)c1 ; c1ccc2c(c1)c1ccccc1n2-c1ccc(-c2ccc(-n3c4ccccc4c4ccccc43)cc2)cc1]

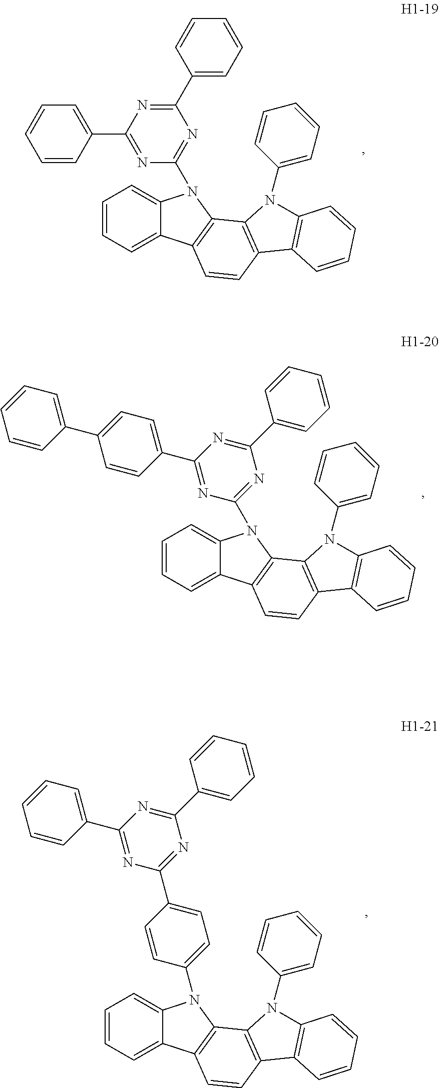 [SMILES: c1ccc(-c2nc(-c3ccccc3)nc(-n3c4ccccc4c4ccc5c6ccccc6n(-c6ccccc6)c5c43)n2)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5ccc6c7ccccc7n(-c7ccccc7)c6c54)cc3)n2)cc1]

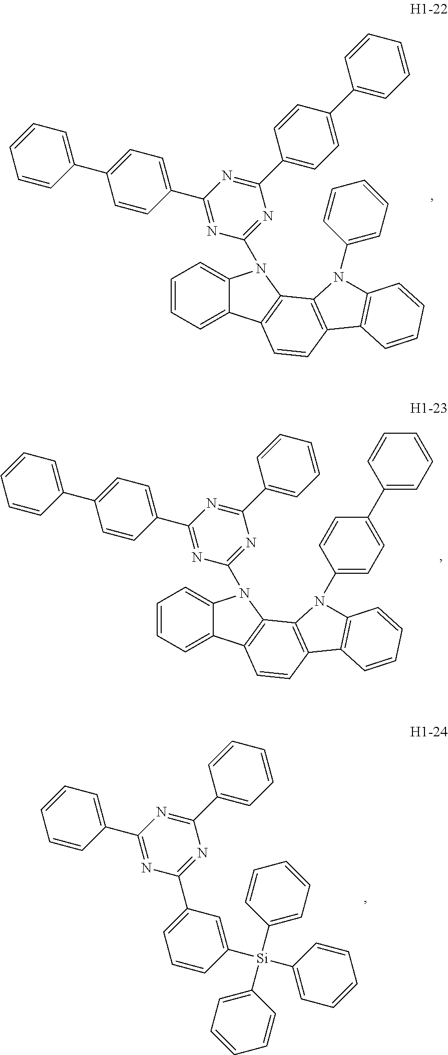 [SMILES: c1ccc(-c2ccc(-c3nc(-c4ccc(-c5ccccc5)cc4)nc(-n4c5ccccc5c5ccc6c7ccccc7n(-c7ccccc7)c6c54)n3)cc2)cc1 ; c1ccc(-c2ccc(-c3nc(-c4ccccc4)nc(-n4c5ccccc5c5ccc6c7ccccc7n(-c7ccc(-c8ccccc8)cc7)c6c54)n3)cc2)cc1 ; c1ccc(-c2nc(-c3ccccc3)nc(-c3cccc([Si](c4ccccc4)(c4ccccc4)c4ccccc4)c3)n2)cc1]

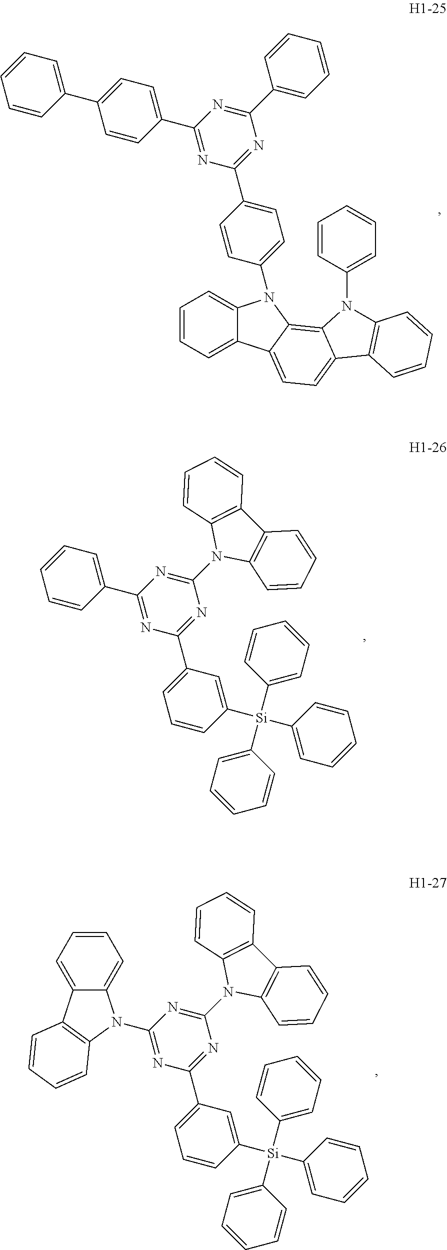 [SMILES: c1ccc(-c2ccc(-c3nc(-c4ccccc4)nc(-c4ccc(-n5c6ccccc6c6ccc7c8ccccc8n(-c8ccccc8)c7c65)cc4)n3)cc2)cc1 ; c1ccc(-c2nc(-c3cccc([Si](c4ccccc4)(c4ccccc4)c4ccccc4)c3)nc(-n3c4ccccc4c4ccccc43)n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

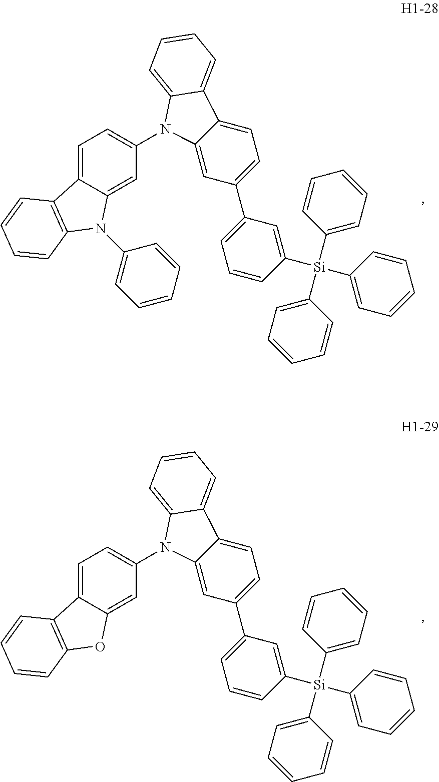 [SMILES: c1ccc(-n2c3ccccc3c3ccc(-n4c5ccccc5c5ccc(-c6cccc([Si](c7ccccc7)(c7ccccc7)c7ccccc7)c6)cc54)cc32)cc1 ; c1ccc([Si](c2ccccc2)(c2ccccc2)c2cccc(-c3ccc4c5ccccc5n(-c5ccc6c(c5)oc5ccccc56)c4c3)c2)cc1]

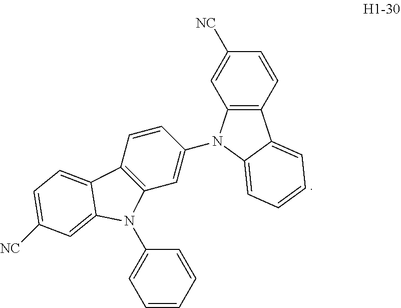 [SMILES: N#Cc1ccc2c3ccccc3n(-c3ccc4c5ccc(C#N)cc5n(-c5ccccc5)c4c3)c2c1]

It will be noted that the structural formulas listed above are examples of the structure of the first host material H1, but not a limitations on the structure of the first host material H1. H1-x in the above structural formulas is an antonomasia of each structural formula, and is not part of the structural formula structure; where x is a positive integer, and the same applies below.

The at least one light-emitting layer 131 further includes a second host material H2, the triplet energy level T1(H2) of the second host material H2, the triplet energy level T1(H1) of the first host material H1, and the triplet energy level T1(D) of the luminescent material D satisfies:

T1(H2)≤T1(H1);T1(H2)≤T1(D).

In the embodiments of the present disclosure, the second host material H2 is provided in the light-emitting layer 131 and the energy transmission direction is set, i.e., since T1(H2)≥T1(D), the second host material H2 can transmit energy to the luminescent material D; moreover, since T1(H2)≤T1(H1), the second host material H2 will not transmit energy to the first host material H1, so that the energy of the second host material H2 can be effectively transmitted to the luminescent material D.

In some embodiments, the difference between the triplet energy level T1(H1) of the first host material H1 and the triplet energy level T1(H2) of the second host material H2 is greater than or equal to 0.1 eV; the difference between the triplet energy level T1(H2) of the second host material H2 and the triplet energy level T1(D) of the luminescent material D is greater than or equal to 0.1 eV.

That is, the triplet energy level T1(H1) of the first host material H1, the triplet energy level T1(H2) of the second host material H2, and the triplet energy level T1(D) of the luminescent material D satisfy:

$$T 1 ( H 1 ) - T 1 ( H 2 ) \geq 0.1 eV ; \\ T 1 ( H 2 ) - T 1 ( D ) \geq 0.1 eV .$$

It can be understood that, by increasing the difference between the triplet energy level T1(H1) of the first host material H1 and the triplet energy level T1(H2) of the second host material H2, and the difference between the triplet energy level T1(H2) of the second host material H2 and the triplet energy level T1(D) of the luminescent material D, it is possible to further ensure that the energy is transmitted in the set direction, that is, the second host material H2 can transmit energy to the luminescent material D, and the second host material H2 does not transmit energy to the first host material H1.

For example, the difference between the triplet energy level T1(H1) of the first host material H1 and the triplet energy level T1(H2) of the second host material H2 is 01 eV, 0.2 eV, 0.4 eV 0.6 eV, 1 eV or the like; the difference between T1(H2) and T1(D) is 0.1 eV, 0.2 eV 0.3 eV, 0.7 eV, 1 eV or the like.

In some embodiments, the difference between a peak wavelength of emission spectrum of the second host material H2 and a peak wavelength of absorption spectrum of the luminescent material D is less than or equal to 40 nm.

It will be noted that, the emission spectrum refers to intensity or energy distribution of light of different wavelengths emitted by the second host material H2 under an excitation of light of a specific wavelength; the absorption spectrum refers to intensity or energy distribution of light of different wavelengths emitted by the luminescent material D under an excitation of light of a specific wavelength.

By setting the difference between the peak wavelength of the emission spectrum of the second host material H2 and the peak wavelength of the absorption spectrum of the luminescent material D to be less than or equal to 40 nm, it is possible to make the second host material H2 transmit energy to the luminescent material D transmit energy to the luminescent material D, thereby effectively improving the luminous efficiency of the light-emitting device 100.

In some embodiments, the difference between the peak wavelength of the emission spectrum of the second host material H2 and the peak wavelength of the absorption spectrum of the luminescent material D is less than or equal to 30 nm. With such arrangement, it is possible to further improve the energy transfer effect of the second host material H2 to the luminescent material D, so as to further improve the luminous efficiency of the light-emitting device 100.

For example, the difference between the peak wavelength of the emission spectrum of the second host material H2 and the peak wavelength of the absorption spectrum of the luminescent material D is 30 nm, 25 nm, 21 nm, 20 nm, or the like.

In some embodiments, singlet energy level S1(H1) of the first host material H1 is greater than or equal to singlet energy level S1(H2) of the second host material H2, and the singlet energy level S1(H2) of the second host material H2 is greater than or equal to singlet energy level S1 (D) of the luminescent material D.

That is, the singlet energy level S1(H1) of the first host material H1, the singlet energy level S1(H2) of the second host material H2, and the singlet energy level S1(D) of the luminescent material D satisfy:

S1(H1)≥S1(H2)≥S1(D).

With such arrangement, the direction of energy transmission at the singlet energy level is: the first host material H1 transfers energy to the second host material H2, and the second host material H2 transfers energy to the luminescent material D, thereby improving the luminous efficiency of the light-emitting device 100.

For example, the singlet energy level S1(H1) of the first host material H1 is greater than the singlet energy level S1(H2) of the second host material H2, and the singlet energy level S1(H2) of the second host material H2 is greater than the singlet energy level S1(D) of the luminescent material D.

In some embodiments, an absolute value of a difference between the highest occupied molecular orbital energy level HOMO(H2) of the second host material H2 and the highest occupied molecular orbital energy level HOMO(H1) of the first host material H1 is less than or equal to 0.3 eV. The absolute value of the difference between the lowest occupied molecular orbital energy level LOMO(H2) of the second host material H2 and the lowest occupied molecular orbital energy level LOMO(D) of the luminescent material D is less than or equal to 0.2 eV; an absolute value of a lowest occupied molecular orbital energy level LOMO(H2) of the second host material H2 is greater than or equal to an absolute value of a lowest occupied molecular orbital energy level LOMO(H1) of the first host material H1; an absolute value of a lowest occupied molecular orbital energy level LOMO(D) of the luminescent material D is greater than or equal to the absolute value of the lowest occupied molecular orbital energy level LOMO(H1) of the first host material H1.

That is, the highest occupied molecular orbital energy level HOMO(H2) of the second host material H2, the highest occupied molecular orbital energy level HOMO(H1) of the first host material H1, the lowest occupied molecular orbital energy level LOMO(H2) of the second host material H2, the lowest occupied molecular orbital energy level LOMO(D) of the luminescent material D, and the lowest occupied molecular orbital energy level LOMO(H1) of the first host material H1 satisfy:

$$\vert HOMO ( H 1 ) - HOMO ( H 2 ) \vert \leq 0.3 eV ;$$

$$\vert LOMO ( H 2 ) - LOMO ( D ) \vert \leq 0.2 eV ;$$

$$\vert LOMO ( H 2 ) \vert \geq \vert LOMO ( H 1 ) \vert ;$$

$$\vert LOMO ( D ) \vert \geq \vert LOMO ( H 1 ) \vert .$$

By limiting the highest occupied molecular orbital energy level HOMO(H2) of the second host material H2, the highest occupied molecular orbital energy level HOMO(H1) of the first host material H1, the lowest occupied molecular orbital energy level LOMO(H2) of the second host material H2, the lowest occupied molecular orbital energy level LOMO(D) of the luminescent material D, and the lowest occupied molecular orbital energy level LOMO(H1) of the first host material H1, it is possible to ensure the balanced transfer of electrons and holes, which makes the energy is transferred to the first host material H1 and the second host material H2 well, and then transferred from the first host material H1 and the second host material H2 to the luminescent material D.

In some embodiments, in each light-emitting layer 131, the difference between the triplet energy level T1(H1) of the first host material H1 and the triplet energy level T1(D) of the light-emitting material D is greater than or equal to 0.15 eV.

That is, in each light-emitting layer 131, the triplet energy level T1(H1) of the first host material H1 and the triplet energy level T1(D) of the light-emitting material D satisfy:

$$T 1 ( H 1 ) - T 1 ( D ) \geq 0.15 eV .$$

By setting the difference between the triplet energy level T1(H1) of the first host material H1 and the triplet energy level T1(D) of the luminescent material D to be greater than or equal to 0.15 eV the luminescent material D is a fluorescent material or delayed fluorescent material, and not a phosphorescent material. Since in the photons emitted by the fluorescent material or the delayed fluorescent material, the proportion of the second luminescent photons is relatively small, it is possible to reduce the delayed luminescent component in the light-emitting unit 130, and improve the response speed of the light-emitting unit 130. Thus, in a case where a certain screen is displayed for a long time and then switched, the tailing and afterimage phenomena of the display screen may be effectively alleviated.

In some embodiments, the second host material H2 is a phosphorescent material and includes any one of ligand groups IA represented by the general formula I.

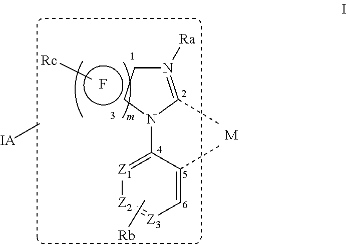

F is selected from a five-membered or six-membered carbocyclic ring or carboheterocyclic ring; the value of m is selected from any one of 0, 1, 2, 3 and 4.

Z₁, Z₂ and Z₃ are the same or different, and are each independently selected from carbon and nitrogen.

The ligand group IA is bonded to M, and M is selected from any one of ruthenium, osmium, iridium, palladium, copper, silver and gold; the second host material H2 includes n-dentate ligand material formed by the structure shown by the general formula I and M, and the value of n is selected from any one of 3, 4, 5 and 6.

Ra, Rb and Rc are the same or different, and are independently selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphine.

At least one of Ra, Rb and Rc contains deuterium. Since deuterium is heavy hydrogen, deuterium substitution is provided on carbon atoms or nitrogen atoms, which may increase the stability of chemical bonds, thereby improving the thermal stability of the second host material H2. It will be noted that, at least one of Ra, Rb and Rc contains deuterium, which means that at least one of Ra, Rb and Rc is deuterium, or at least one of Ra, Rb and Rc is any one of a deuterium-containing alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphine.

It will be noted that, the value of m is selected from any one of 0, 1, 2, 3 and 4. That is, in a case of m=0, F ring does not exist, and the five-membered carbon heterocycle formed by carbons 1, 2, and 3 and nitrogen does not form a fused ring; in a case of m=1, the five-membered carbon heterocycle, formed by carbons 1, 2, and 3 and nitrogen, and one F form a fused ring, and F is selected from a five-membered or six-membered carbon ring or carbon heterocycle; in a case of m=2, the five-membered carbon heterocycle, formed by carbons 1, 2 and 3 and nitrogen, and two F form a fused ring, and the two F are the same or different, and are independently selected from five-membered or six-membered carbocycles or carboheterocycles; in a case of m=3, the five-membered carbon heterocycle, formed by carbons 1, 2 and 3 and nitrogen, and three F form a fused ring, and the three F are the same or different, and are independently selected from five-membered or six-membered carbocycles or carboheterocycles; in a case of m=4, the five-membered carbon heterocycle, formed by carbons 1, 2 and 3 and nitrogen, and four F form a fused ring, and the four F are the same or different, and are independently selected from five-membered or six-membered carbocycles or carboheterocycles.

It can be understood that, the second host material H2 includes an n-dentate ligand material formed by the structure shown by the general formula I and M, and the value of n is selected from any one of 3, 4, 5 and 6; that is, the ligand group IA occupies the first dentate site and the second dentate site of the n-dentate ligand material, and the third dentate site, . . . , and the n-th dentate site of the n-dentate ligand material are occupied by other ligand groups, and the structures of the ligand groups occupying the third dentate site, . . . , and the n-th dentate site of the n-dentate ligand material are not limited in the present disclosure.

It will be noted that, the position of Rb shown in the general formula I means that Rb can be bonded to any one of carbon 6, Z₁, Z₂ and Z₃; that is, Rb can be bonded to any substituent element on the six-membered ring formed by carbon 4, 5, 6, and Z₁, Z₂, and Z₃. As for Rc, reference may be made to the description of Rb, which will not be repeated here.

The ligand group IA of the second host material H2 including the ligand group IA shown in the general formula I contains a carbene group (i.e., the five-membered carbon heterocycle formed by carbons 1, 2, and 3 and nitrogen), and this group can achieve the emission of short-wavelength light, and the color of the short-wavelength light is, for example, dark blue.

In a case where the light emitted by the light-emitting device 100 is blue, due to the provision of the light-emitting layer 131 including the second host material H2, the energy of the second host material H2 may be effectively transmitted to the light-emitting material D, thereby improving the luminous efficiency of the light-emitting device 100, and improve the service life of the light-emitting device 100. Moreover, the second host material H2 may be compatible with the manufacturing process of the light-emitting device in the related art, such as evaporation, which reduces the manufacturing cost of the light-emitting device. In addition, the second host material H2 may increase the number of second luminescent photons among the photons emitted by the light-emitting layer of the blue light-emitting unit 130B, which increases the proportion of the delayed luminescent component in the light-emitting layer of the blue light-emitting unit 130B, so as to achieve the synchronization of emission delay of the red light-emitting unit 130R, the green light-emitting unit 130G, and the blue light-emitting unit 130B to a certain extent. Thus, in a case where a certain screen is displayed for a long time and then switched, the tailing and afterimage phenomena of the display screen may be effectively alleviated.

In some embodiments, the second host material H2 is selected from any one of the structures shown in the following general formula I.

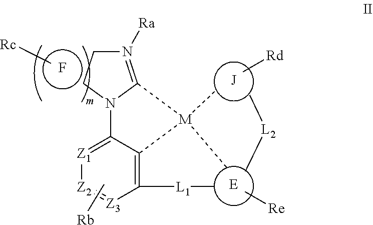

F is selected from a five-membered or six-membered carbocyclic ring or carboheterocyclic ring; the value of m is selected from any one of 0, 1, 2, 3 and 4.

J and E are the same or different, and are independently selected from five-membered or six-membered carbocyclic ring or carboheterocyclic ring.

Z₁, Z₂ and Z₃ are the same or different, and are each independently selected from carbon and nitrogen.

M is selected from one of platinum and palladium.

L₁ and L₂ are the same or different, and are independently selected from any of B(Rf), N(Rf), P(Rf), O, S, Se, C═O, S═O, SO₂, C(Rf Rg), Si(Rf Rg) and Ge(Rf Rg).

Ra, Rb, Rc, Re, Rd, Rf, and Rg are the same or different, and are independently selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphine.

In addition, L₁ and L₂ are different, and at least one of Ra, Rb and Rc contains deuterium. Since deuterium is heavy hydrogen, deuterium substitution is provided on carbon atoms or nitrogen atoms, which may increase the stability of chemical bonds, thereby improving the thermal stability of the second host material H2. It will be noted that, at least one of Ra, Rb and Rc contains deuterium, which means that at least one of Ra, Rb and Rc is deuterium, or at least one of Ra, Rb and Rc is any one of a deuterium-containing alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphine.

It will be noted that, L₁ and L₂ are independently selected from any one of B(Rf), N(Rf), P(Rf), O, S, Se, C═O, S═O, SO₂, C(Rf Rg), Si(Rf Rg) and Ge(Rf Rg). B(Rf) is substituted or unsubstituted boron; N(Rf) is substituted or unsubstituted nitrogen; P(Rf) is substituted or unsubstituted phosphorus; O is oxygen; S is sulfur; Se is selenium; C═O is carbonyl; S═O is thionyl; SO₂ is sulfone; C(Rf Rg) is substituted or unsubstituted carbon; Si(Rf Rg) is substituted or unsubstituted silicon; Ge(Rf Rg) is substituted or unsubstituted germanium.

It will be noted that, as for m here, reference may be made to the above description of m; as for Rb, Rc, Re, Rd, and Rf, reference may be made to the above description of Rb, which will not be repeated here.

In some embodiments, J and E are not both the five-membered carbocyclic ring or carboheterocyclic ring. This is because in a case where J and E are both five-membered carbocyclic ring or carboheterocyclic ring, the stability of the formed compound is relatively poor. Due to the provision of both J and E being not to be the five-membered carbocyclic ring or carboheterocyclic ring, it is possible to improve the stability of the second host material H2.

For example, in a case where M is platinum, m=0, L₁ is oxygen, L₂ is nitrogen, Z₁, Z₂ and Z₃ are carbon, J and E are six-membered carbocyclic ring, and Re and Rf are fused, Ra, Rb, Rc, Re, Rd and Rf are the same or different, and are independently selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphine; at least one of Ra, Rb and Rc is deuterated methyl, and the structural formula of the second host material H2 may be as shown in the following formula,

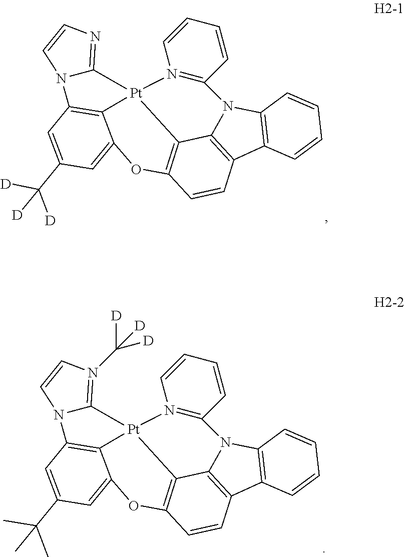

For example, in a case where M is platinum, m=1, L₁ is oxygen, L₂ is nitrogen, Z₁, Z₂ and Z₃ are carbon, J and E are six-membered carbocyclic ring, and Re and Rf are fused, Ra, Rb, Rc, Re, Rd and Rf are the same or different, and are independently selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphine; at least one of Ra, Rb and Rc contains deuterium, and the structural formula of the second host material H2 may be as shown in the following formula.

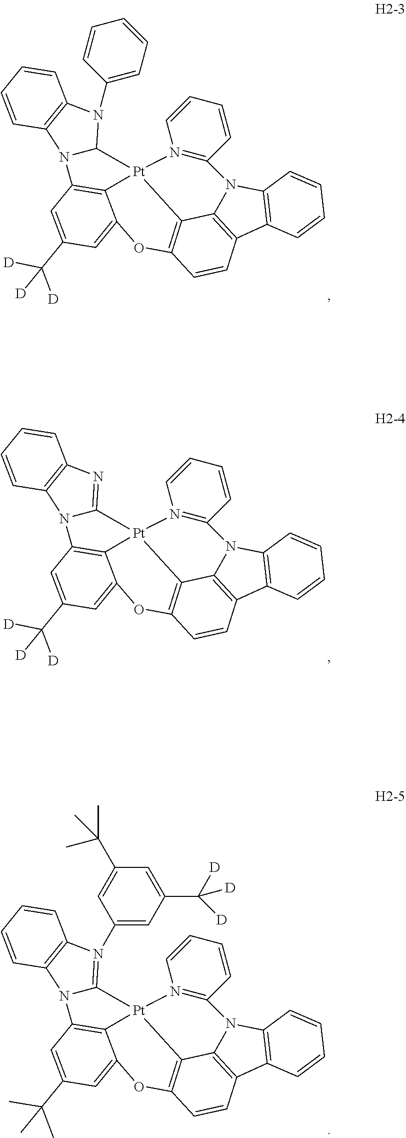

For example, in a case where M is platinum, m=0, L₁ is silicon, L₂ is nitrogen, Z₁, Z₂ and Z₃ are carbon, J and E are six-membered carbocyclic ring, and Re and Rf are fused, Rb, Rc, Re, Rd, Rf and Rg are the same or different, and are independently selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphine; Ra contains deuterated methyl, and the structural formula of the second host material H2 may be as shown in the following formula.

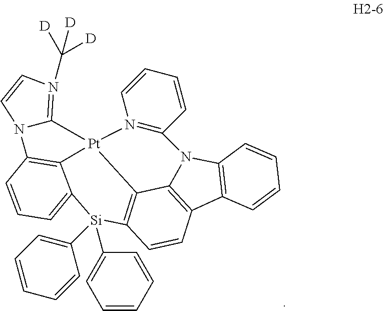

For example, in a case where M is platinum, m=1, L₁ is silicon, L₂ is nitrogen, Z₁, Z₂ and Z₃ are carbon, J and E are six-membered carbocyclic ring, and Re and Rf are fused, Rb, Rc, Re, Rd, Rf and Rg are the same or different, and are independently selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphine; Ra contains deuterated methyl, and the structural formula of the second host material H2 may be as shown in the following formula.

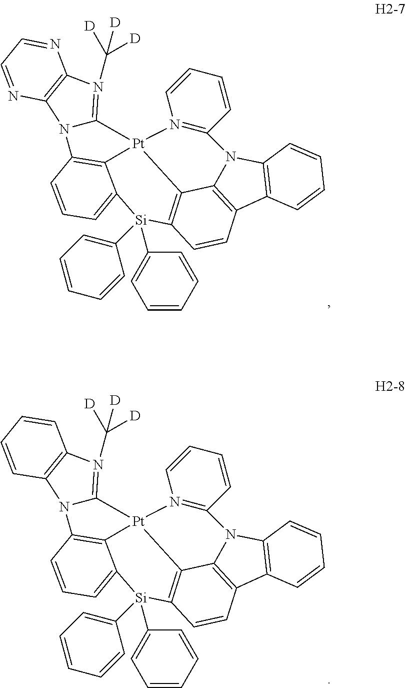

It will be noted that, the structural formulas listed above are examples of the structure of the second host material H2, but not a limitation on the structure of the second host material H2. In the above structural formulas, H2-x is an antonomasia of each structural formula, and is not part of the structural formula structure; x is a positive integer, and the same applies below.

In some embodiments, the mass proportion of the second host material H2 (a phosphorescent material) in the light-emitting layer 131 is greater than or equal to 10% and less than or equal to 50%. For example, the mass proportion of the second host material H2 in the light-emitting layer 131 is 10%, 20%, 30%, 35%, 40%, 50%, or the like. In a case where the mass proportion of the second host material H2 in the light-emitting layer 131 is less than 10%, the charge transfer efficiency will be reduced, resulting in a reduction in the luminous efficiency of the light-emitting device 100. In a case where the mass proportion of the second host material H2 in the light-emitting layer 131 is greater than 50%, the luminous efficiency of the light-emitting device 100 will be reduced.

In some other embodiments, the second host material H2 is a delayed fluorescent material, which is selected from any one of the structures shown in the following general formula III.

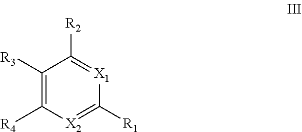

X₁ and X₂ are the same or different, and are independently selected from carbon and nitrogen.

R₁, R₂, R₃ and R₄ are the same or different, and are independently selected from one of a substituted or unsubstituted substituent group IIIA and a substituted or unsubstituted substituent group IIIB; R₁, R₂, R₃ and R₄ contains at least two substituted or unsubstituted substituent groups IIIA and at least one substituted or unsubstituted substituent group IIIB.

The substituent group IIIA is selected from any one of IIIA-a to IIIA-i.

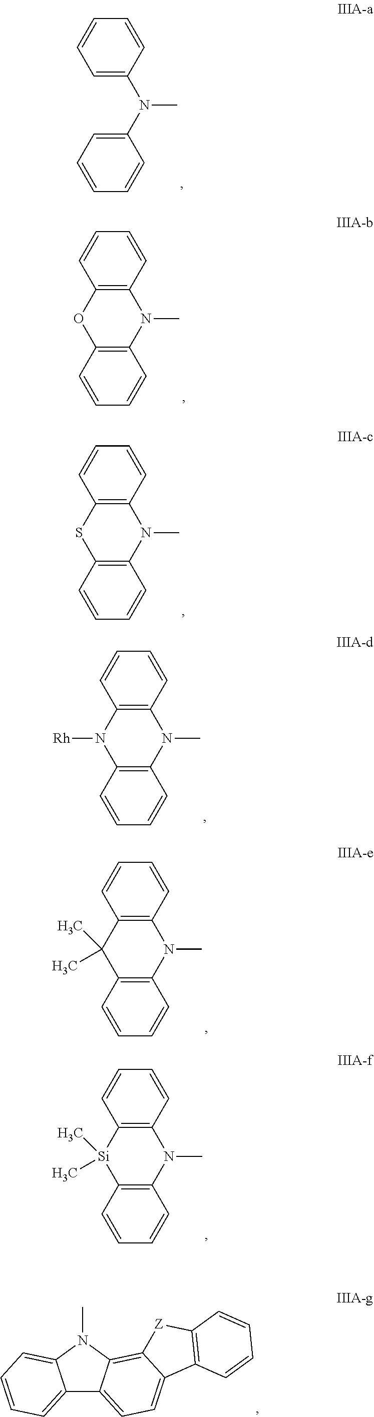

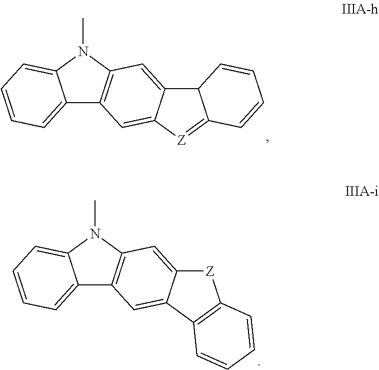

Z is selected from any one of carbon, nitrogen, oxygen and sulfur.

Rh is selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphine.

The substituent group IIIB is selected from any one of IIIB-a to IIIB-j.

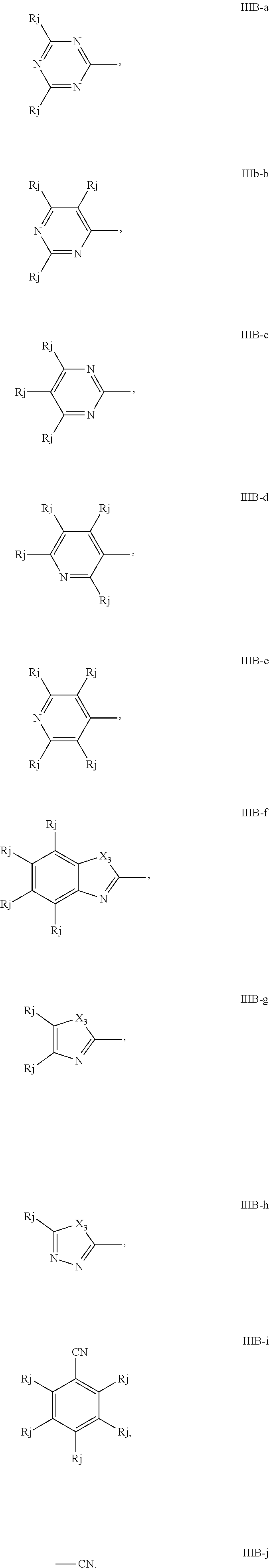

X₃ is selected from oxygen and sulfur.

Rj is selected from any one of hydrogen, deuterium, halogen, nitrile, substituted or unsubstituted alkyl, substituted or unsubstituted haloalkyl, substituted or unsubstituted alkoxy, substituted or unsubstituted haloalkoxy, substituted or unsubstituted aryl, substituted or unsubstituted haloaryl group, substituted or unsubstituted silyl group, and substituted or unsubstituted heterocycle.

It will be noted that two benzene rings in IIIA-a may be bonded through a single bond to form substituted or unsubstituted IIIA-a-1, and its structural formula may be as shown in the following formula.

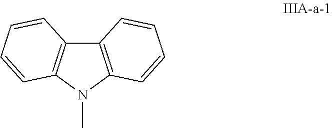

It will be noted that, the structural formulas listed above are examples of the structures of the substituent group IIIA and substituent group IIIB, and are not limitations on the structures of the substituent group IIIA and substituent group IIIB. IIIA-x, IIIB-x in the above structural formulas are each an antonomasia of each structural formula, and are not part of the structural formula structure.

In a case where the light-emitting layer 131 includes a first host material H1, a second host material H2, and a luminescent material D, the second host material H2 selected from the structure shown in general formula III can reduce the number of the second luminescent photons in the photons emitted by the light-emitting layer of the red light-emitting unit 130R and that of the green light-emitting unit 130G, thereby reducing the proportion of delayed luminescent component in the photons emitted by the light-emitting layer of the red light-emitting unit 130R and that of the green light-emitting unit 130G, and improving the response speed of the red light-emitting unit 130R and the green light-emitting unit 130G. In addition, the second host material H2 can increase the number of the second luminescent photons in the photons emitted by the light-emitting layer of the blue light-emitting unit 130B, thereby increasing the proportion of delayed luminescent component in the photons emitted by the light-emitting layer of the blue light-emitting unit 130B, so as to achieve the synchronization of emission delay of the red light-emitting unit 130R, the green light-emitting unit 130G, and the blue light-emitting unit 130B. Thus, in a case where a certain screen is displayed for a long time and then switched, the tailing and afterimage phenomena of the display screen may be effectively alleviated. The luminescent material D is, for example, a fluorescent luminescent material. Furthermore, the second host material H2 selected from the structure shown in general formula III may be compatible with the manufacturing process of the light-emitting device in the related art, such as evaporation, which reduces the manufacturing cost of the light-emitting device.

For example, in a case where X₁ and X₂ are substituted or unsubstituted carbons, at least two of R₁, R₂, R₃ and R₄ are IIIA-a-1, and at least one of R₁, R₂, R₃ and R₄ is IIIB-j, the structural formula of the second host material H2 may be as shown below.

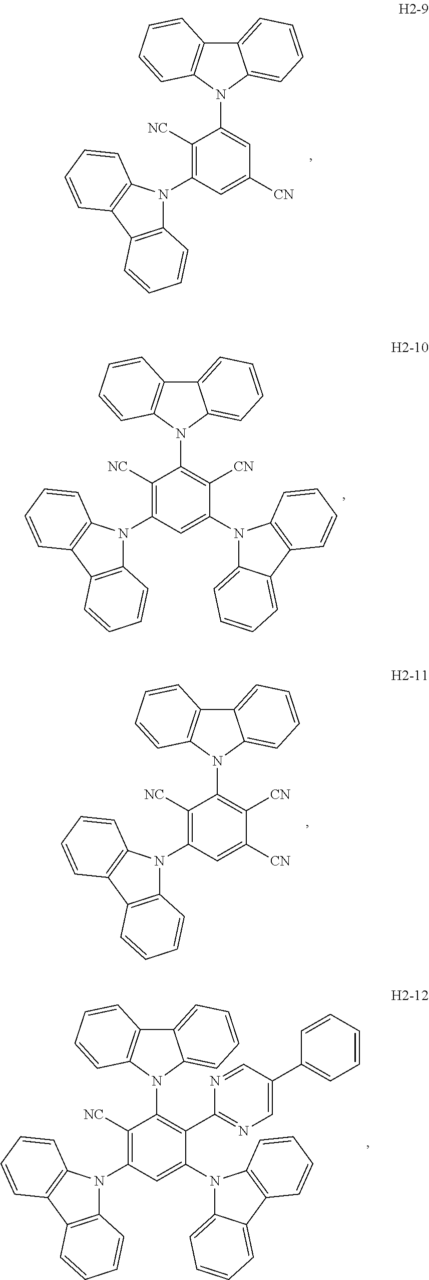 [SMILES: N#Cc1cc(-n2c3ccccc3c3ccccc32)c(C#N)c(-n2c3ccccc3c3ccccc32)c1 ; N#Cc1c(-n2c3ccccc3c3ccccc32)cc(-n2c3ccccc3c3ccccc32)c(C#N)c1-n1c2ccccc2c2ccccc21 ; N#Cc1cc(-n2c3ccccc3c3ccccc32)c(C#N)c(-n2c3ccccc3c3ccccc32)c1C#N ; N#Cc1c(-n2c3ccccc3c3ccccc32)cc(-n2c3ccccc3c3ccccc32)c(-c2ncc(-c3ccccc3)cn2)c1-n1c2ccccc2c2ccccc21]

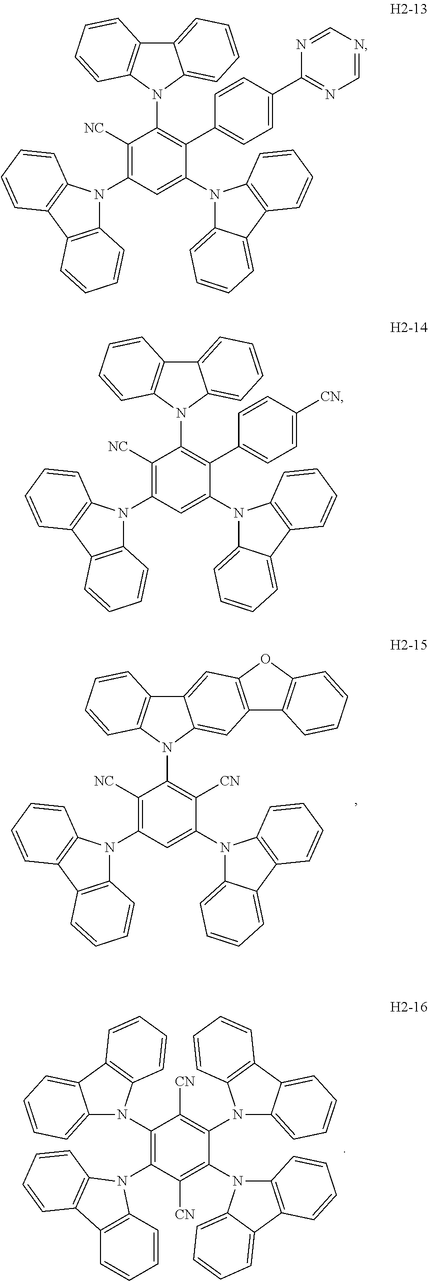

For example, in a case where X₁ and X₂ are substituted or unsubstituted carbons, and R₁, R₂, R₃ and R₄ are Ill A-a-1, Ill A-i, Ill A-h, IIIB-j respectively, the structural formula of the second host material H2 may be as shown below.

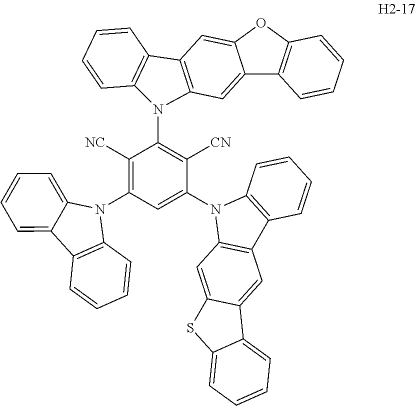 [SMILES: N#Cc1c(-n2c3ccccc3c3ccccc32)cc(-n2c3ccccc3c3cc4c(cc32)sc2ccccc24)c(C#N)c1-n1c2ccccc2c2cc3oc4ccccc4c3cc21]

For example, in a case where X₁ and X₂ are substituted or unsubstituted carbons, three of R₁, R₂, R₃ and R₄ are substituted IIIA-a-1, and one of R₁, R₂, R₃ and R₄ is IIIB-j, the structural formula of the second host material H2 may be as shown below.

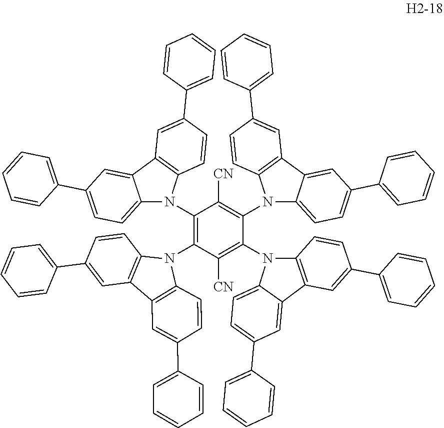 [SMILES: N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)c(C#N)c(-n2c3ccc(-c4ccccc4)cc3c3cc(-c4ccccc4)ccc32)c1-n1c2ccc(-c3ccccc3)cc2c2cc(-c3ccccc3)ccc21]

For example, in a case where X₁ and X₂ are substituted or unsubstituted carbons, one of R₁, R₂, R₃ and R₄ is substituted or unsubstituted IIIA-g, and another of R₁, R₂, R₃ and R₄ is IIIB-a, the structural formula of the second host material H2 may be as shown below.

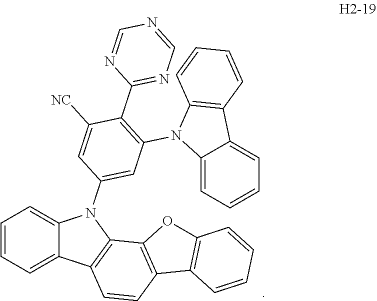 [SMILES: N#Cc1cc(-n2c3ccccc3c3ccc4c5ccccc5oc4c32)cc(-n2c3ccccc3c3ccccc32)c1-c1ncncn1]

For example, in a case where X₁ and X₂ are substituted or unsubstituted carbons, and R₁, R₂, R₃ and R₄ include IIIA-a-1, IIIB-j and unsubstituted IIIB-a, the structural formula of the second host material H2 may be as shown below.

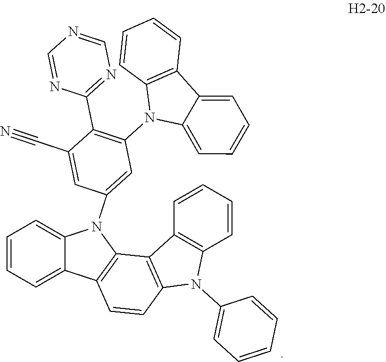 [SMILES: N#Cc1cc(-n2c3ccccc3c3ccc4c(c5ccccc5n4-c4ccccc4)c32)cc(-n2c3ccccc3c3ccccc32)c1-c1ncncn1]

It will be noted that the structural formulas listed above are examples of the structure of the second host material H2, but not limitations on the structure of the second host material H2. H1-x in the above structural formulas is an antonomasia of each structural formula, and is not part of the structural formula structure. x is a positive integer, and the same applies below.

In some embodiments, the mass proportion of the second host material H2 (a delayed fluorescent material) in the light-emitting layer 131 is greater than or equal to 20% and less than or equal to 55%. For example, the mass proportion of the second host material H2 in the light-emitting layer 131 is 20%, 25%, 30%, 40%, 50%, 55%, or the like. In a case where the mass proportion of the second host material H2 in the light-emitting layer 131 is less than 20%, the energy transmission function from the second host material H2 to the luminescent material D can not meet the requirements, resulting in excessive luminescence of the second host material H2 and obvious delay effect. In a case where the mass proportion of the second host material H2 in the light-emitting layer 131 is greater than 55%, the luminous efficiency of the light-emitting device 100 may be reduced.

In some embodiments, the mass proportion of the second host material H2 in the light-emitting layer 131 is less than or equal to the mass proportion of the first host material H1 in the light-emitting layer 131. In a case where the mass proportion of the second host material H2 in the light-emitting layer 131 is greater than the mass proportion of the first host material H1 in the light-emitting layer 131, the luminous efficiency of the light-emitting device 100 may be reduced.

For example, the mass proportion of the second host material H2 in the light-emitting layer 131 is smaller than the mass proportion of the first host material H1 in the light-emitting layer 131.

In some embodiments, referring to FIG. 4, the light-emitting unit 130 includes a plurality of light-emitting layers 131, and the plurality of light-emitting layers 131 are stacked in the first direction X.

In a case where the light-emitting unit 130 includes a plurality of light-emitting layers 131, the plurality of light-emitting layers 131 are stacked in the first direction X from the first electrode 110 to the second electrode 120, which improves the service life of the light-emitting device 100.

It will be noted that, in a case where the light-emitting unit 130 includes a plurality of light-emitting layers 131, the number of types of the material of each light-emitting layer 131 in the plurality of light-emitting layers 131 needs to be consistent. For example, if the light-emitting layer 131 of the light-emitting unit 130 includes the first host material H1, the second host material H2, and the luminescent material D, each light-emitting layer 131 of the plurality of light-emitting layers 131 includes the first host material H1, the second host material H2, and the luminescent material D; alternatively, if the light-emitting layer 131 of the light-emitting unit 130 includes the first host material H1 and the luminescent material D, each light-emitting layer 131 of the plurality of light-emitting layers 131 includes the first host material H1 and the luminescent material D. However, the structure corresponding to each material may be different. For example, if the first host material H1 of the first light-emitting layer 131 among the plurality of light-emitting layers 131 is H1-1, the first host material H1 of the second light-emitting layer 131 among the plurality of light-emitting layers 131 may be H1-2, H1-4, H1-10, or the like. As for the second host material H2 and the luminescent material D, reference may be made to the above description of the first host material H1, which will not be repeated here.

In order to objectively evaluate technical effects of the embodiments of the present disclosure, detailed exemplary description of embodiments of the present application is given through the following Experimental examples and Comparative example.

In the following Embodiments and Comparative example, the light-emitting layer 131 of the light-emitting device 100 is made of different material, and the voltage, luminous efficiency, device life of the light-emitting device 100 are compared; furthermore, the difference ΔBR, for the blue light-emitting unit 130B and the red light-emitting unit 130R, between the ratio of the number of the first luminescent photons to the photons emitted by the light-emitting unit 130; the difference ΔBG, for the blue light-emitting unit 130B and the green light-emitting unit 130G, between the ratio of the number of the first luminescent photons to the photons emitted by the light-emitting unit 130; and the difference ΔGR, for the green light-emitting unit 130G and the red light-emitting unit 130R, between the ratio of the number of the first luminescent photons to the photons emitted by the light-emitting unit 130 are compared.

In the following comparative example and embodiments, the structure of the light-emitting device 100 and the test conditions of the light-emitting device 100 are the same.

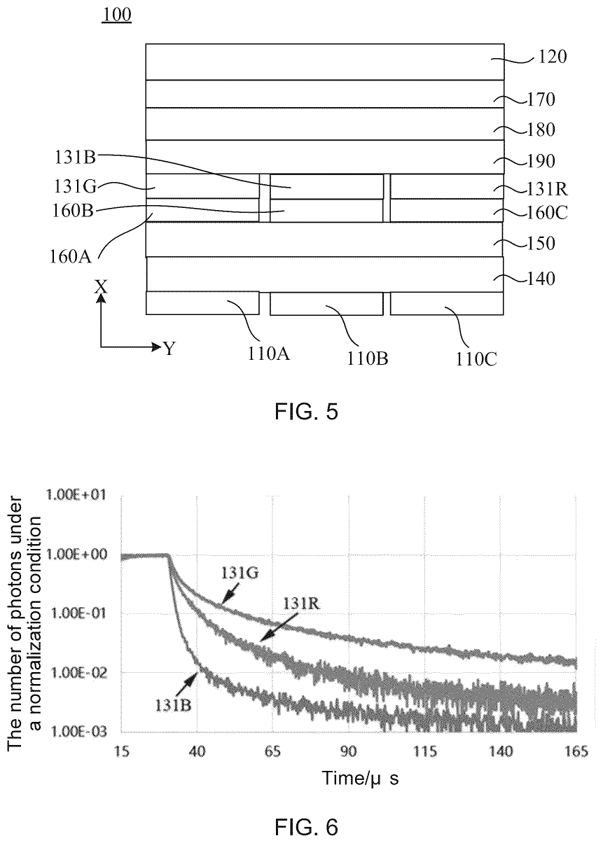

For example, referring to FIG. 5, the method of manufacturing the light-emitting device 100 is as follows: forming the first electrode 110, the hole injection layer 140, the hole transport layer 150, the electron blocking layer 160, the light-emitting layer 131, the hole blocking layer 190, the electron transport layer 180, the electron injection layer 170 and the second electrode 120 on the backplate in sequence by respectively using the material (indium tin oxide) of the first electrode 110, the material of the hole injection layer 140, the material of the hole transport layer 150, the material of the electron blocking layer 160, the material of the light-emitting layer 131, the material of the hole blocking layer 190, the material of the electron transport layer 180, the material of the electron injection layer 170 and the material of the second electrode 120. The process of forming the first electrode 110, the hole injection layer 140, the hole transport layer 150, the electron blocking layer 160, the light-emitting layer 131, the hole blocking layer 190, the electron transport layer 180, the electron injection layer 170 and the second electrode 120 is, for example, evaporation.

The formed light-emitting layer includes a first light-emitting layer 131B that emits blue light, a second light-emitting layer 131G that emits green light, and a third light-emitting layer 131R that emits red light, and the first light-emitting layer 131B, the second light-emitting layer 131G and the third light-emitting layer 131R are arranged in the second direction Y. The first light-emitting layer 131B is the light-emitting layer of the blue light-emitting unit 130B, the second light-emitting layer 131G is the light-emitting layer of the green light-emitting unit 130G, and the third light-emitting layer 131G is the light-emitting layer of the red light-emitting unit 130R. The first electrode 110 includes a first electrode 110A, a first electrode 110B and a first electrode 110C, and the first electrode 110A, the first electrode 110B and the first electrode 110C are arranged in the second direction Y. The electron blocking layer 160 includes an electron blocking layer 160A, an electron blocking layer 160B, and an electron blocking layer 160C, and the electron blocking layer 160A, the electron blocking layer 160B, and the electron blocking layer 160C are arranged in the second direction Y. The first electrode 110A, the electron blocking layer 160A and the first light-emitting layer 131B face each other in the first direction X; the first electrode 110B, the electron blocking layer 160B, and the second light-emitting layer 131G face each other in the first direction X; the first electrode 1100, the electron blocking layer 160C and the third light-emitting layer 131R face each other in the first direction X.

It will be noted that the light-emitting device 100 in the comparative example and the embodiments is a light-emitting device 100 including the single-layer light-emitting layer 131, that is, each light-emitting unit 130 includes one light-emitting layer 131. For the first electrode 110, the hole injection layer 140, the hole transport layer 150, the electron blocking layer 160, the hole blocking layer 190, the electron transport layer 180, the electron injection layer 170, and the second electrode 120 in the embodiments and comparative example, the thickness and material are respectively the same, but the material and thickness of the light-emitting layer 131 are not exactly the same, respectively.

The materials of the first light-emitting layer 131B, the second light-emitting layer 131G, and the third light-emitting layer 131R each include the first host material H1 and the luminescent material D. The luminescent material D involved in the following comparative example and embodiments includes:

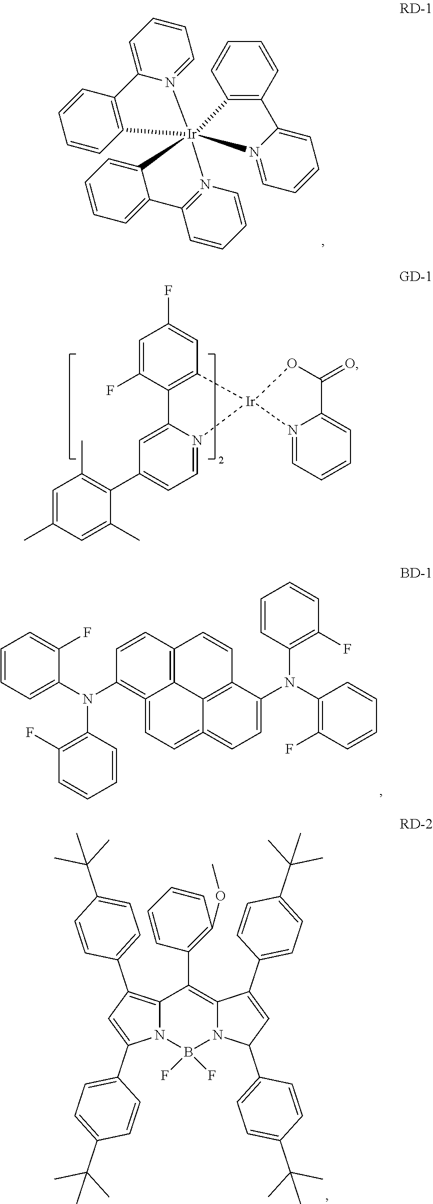

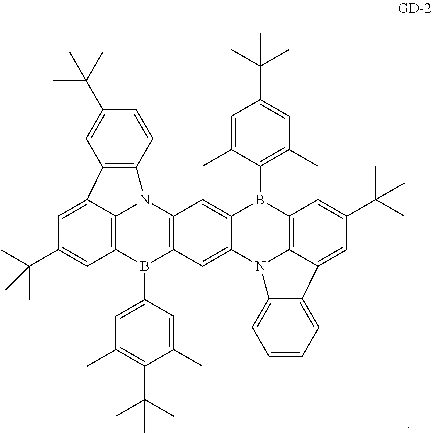 [SMILES: Cc1cc(C(C)(C)C)cc(C)c1B1c2cc3c(cc2-n2c4ccccc4c4cc(C(C)(C)C)cc1c42)B(c1cc(C)c(C(C)(C)C)c(C)c1)c1cc(C(C)(C)C)cc2c4cc(C(C)(C)C)ccc4n-3c12]

It will be noted that, RD-1, GD-1, BD-1, RD-2 and GD-1 in the above structural formulas are each an antonomasia of each structural formula, and not part of the structural formula structure.

The thicknesses and materials of the first light-emitting layer 131B, the second light-emitting layer 131G, and the third light-emitting layer 131R in the embodiments and the comparative example will be described respectively.

In the comparative example, the thickness of the first light-emitting layer 131B is 20 nm, the structural formula of the first host material H1 of the first light-emitting layer 131B is shown in H1-17, and the structural formula of the luminescent material D of the first light-emitting layer 131B is shown in BD-1, the mass proportion of the luminescent material D in the first light-emitting layer 131B is 1%, and the first light-emitting layer 131B does not include the second host material H2. The thickness of the second light-emitting layer 131G is 35 nm, the structural formula of the first host material H1 of the second light-emitting layer 131G is shown in H1-18, the structural formula of the luminescent material D of the second light-emitting layer 131G is shown in GD-1, the mass proportion of the luminescent material D in the second light-emitting layer 131G is 10%, and the second light-emitting layer 131G does not include the second host material H2. The thickness of the third light-emitting layer 131R is 45 nm, the structural formula of the first host material H1 of the third light-emitting layer 131R is shown in H1-18, the structural formula of the luminescent material D of the third light-emitting layer 131R is shown in RD-1, the mass proportion of the luminescent material D in the third light-emitting layer 131R is 7%, and the third light-emitting layer 131R does not include the second host material H2.

In Embodiment 1, the thickness of the first light-emitting layer 131B is 40 nm, the structural formula of the first host material H1 of the first light-emitting layer 131B is shown in H1-19, the structural formula of the luminescent material D of the first light-emitting layer 131B is as shown in BD-1, the mass proportion of the luminescent material D in the first light-emitting layer 131B is 1%, the structural formula of the second host material H2 of the first light-emitting layer 131B is shown in H2-19, and the mass proportion of the second host material H2 in the first light-emitting layer 131B is 30%. The thickness of the second light-emitting layer 131G is 35 nm, the structural formula of the first host material H1 of the second light-emitting layer 131G is shown in H1-18, the structural formula of the luminescent material D of the second light-emitting layer 131G is shown in GD-1, the mass proportion of the luminescent material D in the second light-emitting layer 131G is 10%, and the second light-emitting layer 131G does not include the second host material H2. The thickness of the third light-emitting layer 131R is 45 nm, the structural formula of the first host material H1 of the third light-emitting layer 131R is shown in H1-18, the structural formula of the luminescent material D of the third light-emitting layer 131R is shown in RD-1, the mass proportion of the luminescent material D in the third light-emitting layer 131R is 7%, and the third light-emitting layer 131R does not include the second host material H2.

In Embodiment 2, the thickness of the first light-emitting layer 131B is 40 nm, the structural formula of the first host material H1 of the first light-emitting layer 131B is as shown in H1-19, and the structural formula of the luminescent material D of the first light-emitting layer 131B is shown in BD-1, the mass proportion of the luminescent material D in the first light-emitting layer 131B is 1%, the structural formula of the second host material H2 of the first light-emitting layer 131B is shown in H2-4, and the mass proportion of the second host material H2 in the first light-emitting layer 131B is 15%. The thickness of the second light-emitting layer 131G is 35 nm, the structural formula of the first host material H1 of the second light-emitting layer 131G is shown in H1-18, the structural formula of the luminescent material D of the second light-emitting layer 131G is shown in GD-1, the mass proportion of the luminescent material D in the second light-emitting layer 131G is 10%, and the second light-emitting layer 131G does not include the second host material H2. The thickness of the third light-emitting layer 131R is 45 nm, the structural formula of the first host material H1 of the third light-emitting layer 131R is shown in H1-18, the structural formula of the luminescent material D of the third light-emitting layer 131R is shown in RD-1, the mass proportion of the luminescent material D in the third light-emitting layer 131R is 7%, and the third light-emitting layer 131R does not include the second host material H2.

In Embodiment 3, the thickness of the first light-emitting layer 131B is 20 nm, the structural formula of the first host material H1 of the first light-emitting layer 131B is as shown in H1-17, the structural formula of the luminescent material D of the first light-emitting layer 131B is shown in BD-1, the mass proportion of the luminescent material D in the first light-emitting layer 131B is 1%, and the first light-emitting layer 131B does not include the second host material H2. The thickness of the second light-emitting layer 131G is 35 nm, the structural formula of the first host material H1 of the second light-emitting layer 131G is shown in H1-2, the structural formula of the luminescent material D of the second light-emitting layer 131G is shown in GD-2, the mass proportion of the luminescent material D in the second light-emitting layer 131G is 1%, the structural formula of the second host material H2 of the second light-emitting layer 131G is shown in H2-16, and the mass proportion of the second host material H2 in the second light-emitting layer 131G is 30%. The thickness of the third light-emitting layer 131R is 45 nm, the structural formula of the first host material H1 of the third light-emitting layer 131R is shown in H1-6, the structural formula of the luminescent material D of the third light-emitting layer 131R is shown in RD-2, the mass proportion of the luminescent material D in the third light-emitting layer 131R is 1%, the structural formula of the second host material H2 of the third light-emitting layer 131 is shown in H2-10, and the mass proportion of the second host material H2 in the third light-emitting layer 131R is 20%.

In Embodiment 4, the thickness of the first light-emitting layer 131B is 20 nm, the structural formula of the first host material H1 of the first light-emitting layer 131B is as shown in H1-17, the structural formula of the luminescent material D of the first light-emitting layer 131B is shown in BD-1, the mass proportion of the luminescent material D in the first light-emitting layer 131B is 1%, and the first light-emitting layer 131B does not include the second host material H2. The thickness of the second light-emitting layer 131G is 35 nm, the structural formula of the first host material H1 of the second light-emitting layer 131G is shown in H1-8, the structural formula of the luminescent material D of the second light-emitting layer 131G is shown in GD-2, the mass proportion of the luminescent material D in the second light-emitting layer 131G is 1%, the structural formula of the second host material H2 of the second light-emitting layer 131G is shown in H2-16, and the mass proportion of the second host material H2 in the second light-emitting layer 131G is 30%. The thickness of the third light-emitting layer 131R is 45 nm, the structural formula of the first host material H1 of the third light-emitting layer 131R is shown in H1-6, the structural formula of the luminescent material D of the third light-emitting layer 131R is shown in RD-2, the mass proportion of the luminescent material D in the third light-emitting layer 131R is 1%, the structural formula of the second host material H2 of the third light-emitting layer 131R is shown in H2-10, and the mass proportion of the second host material H2 in the third light-emitting layer 131R is 35%.

In Embodiment 5, the thickness of the first light-emitting layer 131B is 40 nm, the structural formula of the first host material H1 of the first light-emitting layer 131B is as shown in H1-19, and the structural formula of the luminescent material D of the first light-emitting layer 131B is shown in BD-1, the mass proportion of the luminescent material D in the first light-emitting layer 131B is 1%, the structural formula of the second host material H2 of the first light-emitting layer 131B is shown in H2-19, and the mass proportion of the second host material H2 in the first light-emitting layer 131B is 30%. The thickness of the second light-emitting layer 131G is 35 nm, the structural formula of the first host material H1 of the second light-emitting layer 131G is shown in H1-8, the structural formula of the luminescent material D of the second light-emitting layer 131G is shown in GD-2, the mass proportion of the luminescent material D in the second light-emitting layer 131G is 1%, the structural formula of the second host material H2 of the second light-emitting layer 131G is shown in H2-16, and the mass proportion of the second host material H2 in the second light-emitting layer 131G is 30%. The thickness of the third light-emitting layer 131R is 45 nm, the structural formula of the first host material H1 of the third light-emitting layer 131R is shown in H1-6, the structural formula of the luminescent material D of the third light-emitting layer 131R is shown in RD-2, the mass proportion of the luminescent material D in the third light-emitting layer 131R is 10%, the structural formula of the second host material H2 of the third light-emitting layer 131R is shown in H2-10, the mass proportion of the second host material H2 in the third light-emitting layer 131R is 35%.

In order to more clearly describe the differences in the structural formulas, mass proportions in the light-emitting layer 131, and thicknesses of the first host material H1, the second host material H2 and the luminescent material D used in the Embodiments and Comparative example, Table 1 is used to more clearly describe the differences in the structural formulas, mass proportions in the light-emitting layer 131, and thicknesses of the first host material H1, the second host material H2 and the

TABLE 1

| | | Comparative | | | | | |
|---|---|---|---|---|---|---|---|
| | | example | Embodiment 1 | Embodiment 2 | Embodiment 3 | Embodiment 4 | Embodiment 5 |
| Frist | Thickness(nm) | 20 | 40 | 40 | 20 | 20 | 40 |
| light-emitting | First host material | H1-17 | H1-19 | H1-19 | H1-17 | H1-17 | H1-19 |
| layer | Second host material | / | H2-19; | H2-4; | / | / | H2-19; |
| | and mass proportion | | 30% | 15% | | | 30% |
| | Luminescence material | BD-1; | BD-1; | BD-1; | BD-1; | BD-1; | BD-1; |
| | and mass proportion | 1% | 1% | 1% | 1% | 1% | 1% |
| Second | Thickness (nm) | 35 | 35 | 35 | 35 | 35 | 35 |
| light-emitting | First host material | H1-18 | H1-18 | H1-18 | H1-2 | H1-8 | H1-8 |
| layer | Second host material | / | / | / | H2-16; | H2-16; | H2-16; |
| | and mass proportion | | | | 30% | 30% | 30% |
| | Luminescence material | GD-1; | GD-1; | GD-1; | GD-2; | GD-2; | GD-2; |
| | and mass proportion | 10% | 10% | 10% | 1% | 1% | 1% |
| Third | Thickness(nm) | 45 | 45 | 45 | 45 | 45 | 45 |
| light-emitting | First host material | H1-18 | H1-18 | H1-18 | H1-6 | H1-6 | H1-6 |
| layer | Second host material | / | / | / | H2-10; | H2-10; | H2-10; |
| | and mass proportion | | | | 20% | 35% | 35% |
| | Luminescence material | RD1; | RD-1; | RD-1; | RD-2; | RD-2; | RD-2; |
| | and mass proportion | 7% | 7% | 7% | 1% | 1% | 1% |

It will be noted that “/” in Table 1 means that the light-emitting layer 131 does not include the second host material H2. For example, “/” in the subgrid corresponding to the second host material H2 and its mass proportion of the first light-emitting layer 131B in the comparative example means that the first light-emitting layer 131B in the comparative example does not include the second host material H2. “A-x; y %” in Table 1 means that the corresponding structural formula is A-x and the corresponding mass proportion is y %. For example, “BD-1; 1%” in the subgrid corresponding to the luminescent material D and its mass proportion of the first light-emitting layer 131B in the comparative example means that for the first light-emitting layer 131B in the comparative example, the structural formula of the luminescent material D is BD-1, and the mass proportion of the luminescent material D in the first light-emitting layer 131B is 1%. As for the structural formulas represented by H1-x, H2-x, BD-x, GD-x, and RD-x (x is a positive integer), reference is made to the above content, which will not be repeated here.

The highest occupied molecular orbital energy level (HOMO), the lowest occupied molecular orbital energy level (LOMO) and the triplet energy level (T1) of the first host material H1 and the second host material H2 shown in Table 1 are as shown in Table 2 below.

TABLE 2

| Compound | HOMO (eV) | LUMO (eV) | T1 (eV) |
|---|---|---|---|
| H1-2 | −5.95 | −2.46 | 2.7 |
| H1-8 | −6.11 | −2.61 | 2.85 |
| H1-6 | −5.92 | −2.52 | 2.86 |
| H1-17 | −5.9 | −2.43 | 3 |
| H1-18 | −5.95 | −2.9 | 2.66 |
| H1-19 | −6.05 | −2.68 | 3.1 |
| H2-19 | −5.95 | −2.59 | 2.75 |
| H2-16 | −5.92 | −3.42 | 2.55 |
| H2-10 | −6.0 | −3.65 | 2.3 |
| H2-4 | 5.78 | −2.49 | 2.72 |

Based on the above materials, the performance of voltage (V), luminous efficiency (cd/A) and device life (h) of the light-emitting device 100 in Embodiments 1 to 5 and Comparative example are tested. The data results are based on the comparative example, and the test results are shown in Table 3 below.

TABLE 3

| | Light-emitting layer B | | | Light-emitting layer G | | | Light-emitting layer R | | |
|---|---|---|---|---|---|---|---|---|---|
| | | Luminous | Device | | Luminous | Device | | Luminous | Device |
| | Voltage | efficiency | life | Voltage | efficiency | life | Voltage | efficiency | life |
| Comparative | 100% | 100% | 100% | 100% | 100% | 100% | 100% | 100% | 100% |
| example | | | | | | | | | |
| Embodiment 1 | 101% | 220% | 90% | 100% | 100% | 100% | 100% | 100% | 100% |
| Embodiment 2 | 102% | 195% | 85% | 100% | 100% | 100% | 100% | 100% | 100% |
| Embodiment 3 | 100% | 100% | 100% | 101% | 109% | 101% | 98% | 98% | 105% |
| Embodiment 4 | 100% | 100% | 100% | 97% | 115% | 121% | 98% | 97% | 130% |
| Embodiment 5 | 101% | 220% | 90% | 97% | 115% | 121% | 98% | 97% | 130% |

It can be seen from Table 3 that, with the test data in Comparative example as a reference, data of the voltage, luminous efficiency and device life thereof are set to 100%. Compared with Embodiments 1 to 5 and Comparative example, in a case where the first light-emitting layer 131B includes the second host material H2, the luminous efficiency is significantly improved; in a case where the second light-emitting layer 131G includes the second host material H2, the luminous efficiency and device life are all improved; in a case where the third light-emitting layer 131R includes the second host material H2, the device life is improved.

Based on the above materials, in the light-emitting device 100 in Embodiments 1 to 5 and Comparative example, for any two light-emitting layers 131, the difference ΔBR, ΔBG, and ΔGR of the ratio of the number of first luminescent photons to the number of photons emitted by the light-emitting layer 131 are calculated. Here, as for the meanings of ΔBR, ΔBG, and ΔGR, reference is made to the above content, which will not be repeated here. The specific calculation method is as follows: first, the ratio E1 of the number of first luminescent photons of each light-emitting layer 131 to the number of photons emitted by the light-emitting layer 131 (hereinafter referred to as an instantaneous luminous ratio E1), the ratio E2 of the number of second luminescent photons of the light-emitting layer 131 to the number of photons emitted by the light-emitting layer 131 (hereinafter referred to as a delayed luminous ratio E2) are obtained by measurement, and then the absolute value of the difference between the instantaneous luminous ratio E1 and the delayed light-emitting ratio E2 is calculated.

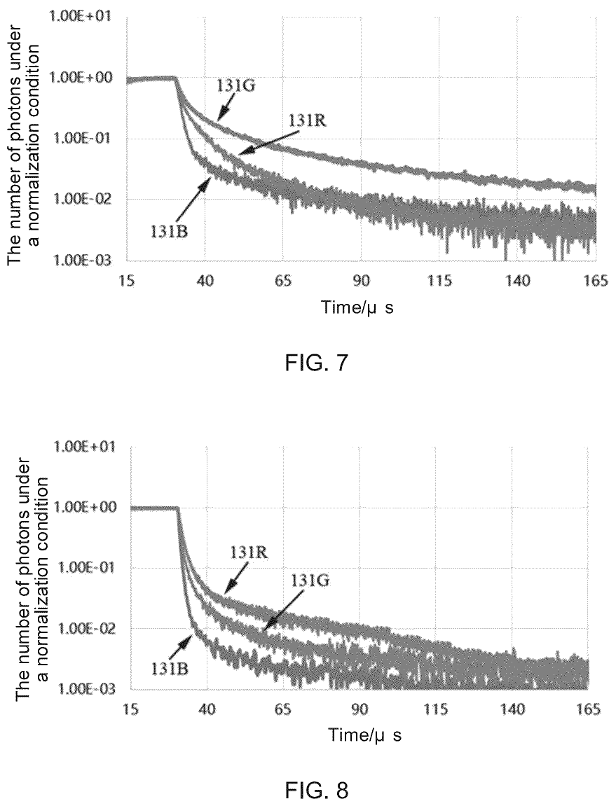

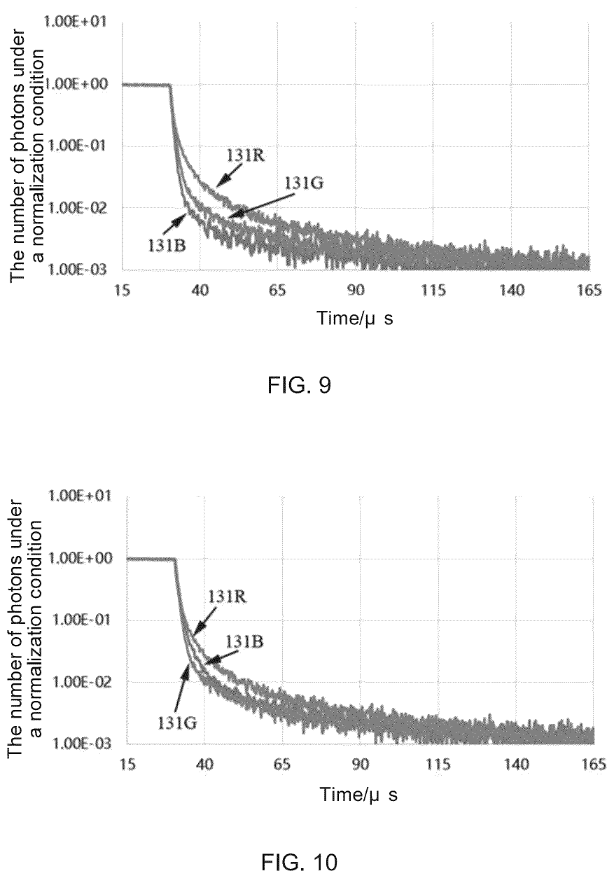

The method of measuring the instantaneous luminescence ratio E1 and the delayed luminescence ratio E2 of each light-emitting layer 131 is, for example, fitting the transient decay curve; the transient decay curve corresponding to the first light-emitting layer 131B, the second light-emitting layer 131G and the third light-emitting layer 131R in Embodiment 1 is shown in FIG. 6, the transient decay curve corresponding to the first light-emitting layer 131B, the second light-emitting layer 131G and the third light-emitting layer 131R in Embodiment 2 is shown in FIG. 7, the transient decay curve corresponding to the first light-emitting layer 131B, the second light-emitting layer 131G and the third light-emitting layer 131R in Embodiment 3 is shown in FIG. 8, the transient decay curve corresponding to the first light-emitting layer 131B, the second light-emitting layer 131G and the third light-emitting layer 131R in Embodiment 4 is shown in FIG. 9, and the transient decay curve corresponding to the first light-emitting layer 131B, the second light-emitting layer 131G and the third light-emitting layer 131R in Embodiment 5 is shown in FIG. 10.

It will be noted that, the number of photons under the normalization condition in FIGS. 6 to 10 refers to the number of photons under the condition that the number of photons emitted by the light-emitting layer 131 is normalized to 1, i.e., the number of photons emitted at a certain time in the figure is the ratio of the number of photons emitted at that time to the number of photons emitted by the light-emitting layer 131.

Specifically, ΔBR is the absolute value of the difference between the instantaneous luminescence ratio B-E1 of the first light-emitting layer 131B and the instantaneous luminescence ratio R-E1 of the third light-emitting layer 131R; ΔBG is the absolute value of the difference between the instantaneous luminescence ratio B-E1 of the first light-emitting layer 131B and the instantaneous luminescence ratio G-E1 of the third light-emitting layer 131G, and ΔGR is the absolute value of the difference between the instantaneous luminescence ratio G-E1 of the second light-emitting layer 131G and the instantaneous luminescence ratio R-E1 of the third light-emitting layer 131R. It will be noted that ΔGR calculated by this method is the same as the ΔGR calculated by the above formula (1). Those skilled in the art can understand that G-E1 in this method is

$$\frac{G 1}{G 1 + G 2} \times 100 \%$$

in the formula (1).

Calculation results of ΔBR, ΔBG, and ΔGR are as shown in Table 4 below.

TABLE 4

| | B-E1 | B-E2 | G-E1 | G-E2 | R-E1 | R-E2 | ΔBG | ΔBR | ΔGR |
|---|---|---|---|---|---|---|---|---|---|
| Comparative | 81.6% | 18.5% | 41.0% | 59.0% | 35.6% | 64.4% | 40.6% | 46.0% | 5.4% |
| example | | | | | | | | | |
| Embodiment 1 | 70.8% | 29.2% | 41.0% | 59.0% | 35.6% | 64.4% | 29.8% | 35.2% | 5.4% |
| Embodiment 2 | 57.4% | 42.6% | 41.0% | 59.0% | 35.6% | 64.4% | 16.4% | 21.8% | 5.4% |
| Embodiment 3 | 81.6% | 18.5% | 55.1% | 44.9% | 57.4% | 42.6% | 26.5% | 24.2% | 2.3% |
| Embodiment 4 | 81.6% | 18.5% | 74.2% | 25.8% | 65.6% | 34.4% | 7.3% | 16.0% | 8.6% |
| Embodiment 5 | 70.8% | 29.2% | 74.2% | 25.8% | 65.6% | 34.4% | 3.4% | 5.2% | 8.6% |

Compared with Embodiments 1 and 2 and Comparative example, ΔBR and ΔBG in Embodiment 1 and Embodiment 2 are significantly reduced, and both Embodiment 1 and Embodiment 2 show that ΔBR, ΔBG, and ΔGR tend to be consistent. This is because the second host material H2-19 (the delayed fluorescent material) is included in the first light-emitting layer 131B in Embodiment 1, and the second host material H2-4 (the phosphorescent material) is included in the first light-emitting layer 131B in Embodiment 2, and the second host materials H2-19 and H2-4 are configured to increase energy transfer. In this case, since the exciton utilization rate of the triplet energy level of the second host material H2 is much higher than that of the triplet state of the first host material H1 in Comparative example, the number of second luminescent photons among the photons emitted by the first light-emitting layer 131B is increased, the proportion of delayed luminescence is increased, so that the difference between the proportion of delayed luminescence of the first light-emitting layer 131B and the second light-emitting layer 131G and that of the first light-emitting layer 131B and the third light-emitting layer 131R, so as to achieve the synchronization of the luminescence delay of the first light-emitting layer 131B, the second light-emitting layer 131G and the third light-emitting layer 131R, i.e. achieve the synchronization of delay of three colors of R, G, and B. Furthermore, compared with Comparative example, the device efficiency is greatly improved, and under the same brightness, the device life is further improved.

Compared with Embodiments 3 and 4 and Comparative example, ΔBR, ΔBG, and ΔGR in Embodiment 3 are significantly reduced, ΔBR and ΔBG in Embodiment 4 are significantly reduced, and both Embodiments 3 and 4 show that ΔBR, ΔBG, ΔGR tends to be consistent. This is because in Embodiments 3 and 4, the second host material H2-16 is included in the second light-emitting layer 131G, and the second host material H2-10 is included in the third light-emitting layer 131R, and the second host materials H2-16 and H2-10 are configured to increase energy transfer, which can generate excitons in the second host material H2 and transfer the exciton energy to the luminescent material D to emit light. Thus, it is possible to increase the delayed life of the triplet energy level of the second host material H2. Compared with Comparative example, among the photons emitted by the third light-emitting layer 131R and the second light-emitting layer 131G, the number of second luminescent photons is reduced, and the proportion of delayed luminescence is reduced, thereby reducing the difference between the delayed luminescence ratio of the first light-emitting layer 131B and the second light-emitting layer 131G and the delayed luminescence ratio of the first light-emitting layer 131B and the third light-emitting layer 131R, so as to achieve the synchronization of the luminescence delay of the first light-emitting layer 131B, the second light-emitting layer 131G and the third light-emitting layer 131R, i.e. achieve the synchronization of delay of three colors of R, G, and B. Furthermore, compared with Comparative example, the internal quantum efficiency in the light-emitting layer 131 can theoretically reach 100%, and the device efficiency is good.

Compared with Embodiment 3 and Embodiment 4, ΔBR in Embodiment 4 is significantly reduced, and ΔBR, ΔBG, and ΔGR tend to be consistent. This is because the first host material H1 of the second light-emitting layer 131G in Embodiment 3 is H1-2, and the first host material H1 of the second light-emitting layer 131G in Embodiment 4 is H1-8. In this case, the triplet energy level of the first host material H1 of the second light-emitting layer 131G in Embodiment 3 is different from that in Embodiment 4, and for the second light-emitting layer 131G, the difference between the triplet energy level of the first host material H1 and the triplet energy level of the second host material H2 is relatively large; in a case where the difference between the triplet energy level of the first host material H1 and the triplet energy level of the second host material H2 is relatively large, it is possible to avoid the exciton leakage from the second main material H2 to the first main material H1 well to reduce the energy relaxation channel, so that among the photons emitted by the second light-emitting layer 131G, the number of second luminescent photons is reduced, and the proportion of delayed luminescence is reduced.

Embodiment 5 is an embodiment obtained after further optimization of Embodiment 3 and Embodiment 4, i.e., the second host material H2 is included in the first light-emitting layer 131B, the second light-emitting layer 131G and the third light-emitting layer 131R. The use of the same light-emitting mechanism is more conducive to adjusting the proportion of instantaneous delayed luminescence and the proportion of delayed luminescence in the three light-emitting layers 131, so as achieve the device performance of high efficiency, long service life, and low delay.

It can be seen that due to the provision of the second host material H2 in the light-emitting layer 131, the proportion of instantaneous delayed luminescence and the proportion of delayed luminescence in the three light-emitting layers 131 can be adjusted, which may effectively reduce the response speed difference between the different light-emitting layers, so as to achieve the sensitized performance of the device of high efficiency, long service life, and low delay. Thus, the problems of slight smearing or image retention may be effectively ameliorated, so as to achieve the high quality image display effect.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting device, comprising:
a first electrode and a second electrode arranged in a first direction in sequence; and
at least two light-emitting units provided between the first electrode and the second electrode, the at least two light-emitting units being arranged in a second direction, and the second direction intersecting the first direction; wherein
photons emitted by each light-emitting unit of the at least two light-emitting units include first luminescent photons and second luminescent photons, and emission time of the first luminescent photons is less than emission time of the second luminescent photons;
wherein the number of second luminescent photons emitted by at least one light-emitting unit is less than or equal to the number of first luminescent photons emitted by the at least one light-emitting unit.

2. The light-emitting device according to claim 1, wherein the at least two light-emitting units include at least three light-emitting units, and the at least three light-emitting units are arranged in the second direction;
under a normalization condition, for any two light-emitting units, a difference of a ratio of the number of first luminescent photons to the number of photons emitted by a light-emitting unit is less than or equal to 40%.

3. The light-emitting device according to claim 1=, wherein each light-emitting unit of the at least two light-emitting units includes at least one light-emitting layer;
each light-emitting layer of the at least one light-emitting layer includes a first host material and a luminescent material, and the at least one light-emitting layer further includes a second host material;
wherein triplet energy level of the second host material is less than or equal to triplet energy level of the first host material, and the triplet energy level of the second host material is greater than or equal to triplet energy level of the luminescent material.

4. The light-emitting device according to claim 3, wherein a difference between the triplet energy level of the first host material and the triplet energy level of the second host material is greater than or equal to 0.1 eV, and a difference between the triplet energy level of the second host material and the triplet energy level of the luminescent material is greater than or equal to 0.1 eV.

5. The light-emitting device according to claim 3, wherein a difference between a peak wavelength of an emission spectrum of the second host material and a peak wavelength of an absorption spectrum of the luminescent material is less than or equal to 40 nm.

6. The light-emitting device according to claim 3, wherein a difference between a peak wavelength of an emission spectrum of the second host material and a peak wavelength of an absorption spectrum of the luminescent material is less than or equal to 30 nm.

7. The light-emitting device according to claim 3, wherein singlet energy level of the first host material is greater than or equal to singlet energy level of the second host material, and the singlet energy level of the second host material is greater than or equal to singlet energy level of the luminescent material.

8. The light-emitting device according to claim 3, wherein
an absolute value of a difference between a highest occupied molecular orbital energy level of the second host material and a highest occupied molecular orbital energy level of the first host material is less than or equal to 0.3 eV;
an absolute value of a difference between a lowest occupied molecular orbital energy level of the second host material and a lowest occupied molecular orbital energy level of the luminescent material is less than or equal to 0.2 eV;
an absolute value of the lowest occupied molecular orbital energy level of the second host material is greater than or equal to an absolute value of a lowest occupied molecular orbital energy level of the first host material; and
an absolute value of a lowest occupied molecular orbital energy level of the luminescent material is greater than or equal to the absolute value of the lowest occupied molecular orbital energy level of the first host material.

9. The light-emitting device according to claim 3, wherein in each light-emitting layer, the difference between the triplet energy level of the first host material and the triplet energy level of the luminescent material is greater than or equal to 0.15 eV.

10. The light-emitting device according to claim 3, wherein the second host material includes any one of ligand groups IA represented by a general formula I; 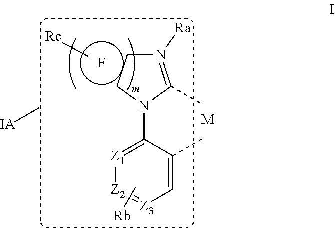
F is selected from a five-membered or six-membered carbocyclic ring or carboheterocyclic ring; a value of m is selected from any one of 0, 1, 2, 3 and 4;
Z₁, Z₂ and Z₃ are the same or different, and are each independently selected from carbon and nitrogen;
the ligand group IA is bonded to M, and M is selected from any one of ruthenium, osmium, iridium, palladium, copper, silver and gold; the second host material includes n-dentate ligand material formed by the structure shown by the general formula I and M, and a value of n is selected from any one of 3, 4, 5 and 6; and
Ra, Rb and Rc are the same or different, and are independently selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphine.

11. The light-emitting device according to claim 3, wherein the second host material is selected from any one of structures represented by the following general formula II; 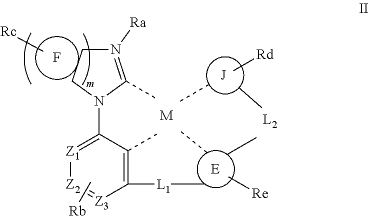
F is selected from a five-membered or six-membered carbocyclic ring or carboheterocyclic ring; a value of m is selected from any one of 0, 1, 2, 3 and 4;
J and E are the same or different, and are independently selected from a five-membered or six-membered carbocyclic ring or carboheterocyclic ring;
Z₁, Z₂ and Z₃ are the same or different, and are each independently selected from carbon and nitrogen;
M is selected from one of platinum and palladium;
L₁ and L₂ are the same or different, and are independently selected from any of B(Rf), N(Rf), P(Rf), O, S, Se, C═O, S═O, SO₂, C(Rf Rg), Si(Rf Rg) and Ge(Rf Rg); and
Ra, Rb, Rc, Re, Rd, Rf, and Rg are the same or different, and are independently selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphine.

12. The light-emitting device according to claim 11, wherein J and E are not both the five-membered carbocyclic ring or carboheterocyclic ring; and/or
L₁ and L₂ are different.

13. (canceled)

14. The light-emitting device according to claim 10, wherein at least one of Ra, Rb and Rc contains deuterium.

15. The light-emitting device according to claim 10, wherein a mass proportion of the second host material in the light-emitting layer is greater than or equal to 10% and less than or equal to 50%.

16. The light-emitting device according to claim 3, wherein the second host material is selected from any one of structures represented by the following general formula III; 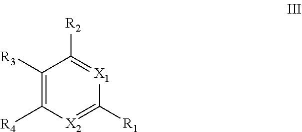
wherein X₁ and X₂ are the same or different, and are independently selected from carbon and nitrogen;
R₁, R₂, R₃ and R₄ are the same or different, and are independently selected from one of a substituted or unsubstituted substituent group IIIA and a substituted or unsubstituted substituent group IIIB; R₁, R₂, R₃ and R₄ contains at least two substituted or unsubstituted substituent groups IIIA and at least one substituted or unsubstituted substituent group IIIB;
the substituent group IIIA is selected from any one of IIIA-a to IIIA-i; 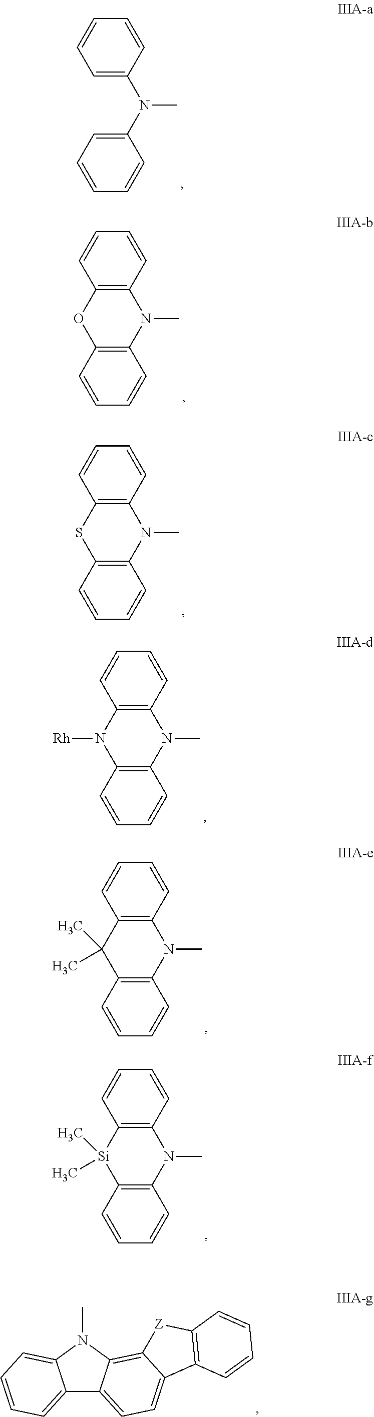 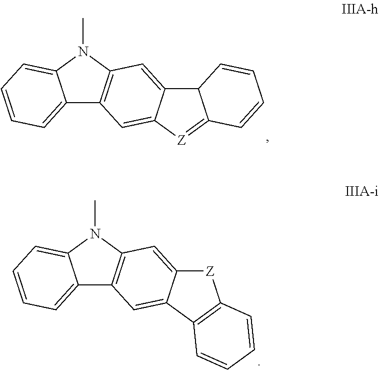
Z is selected from any one of carbon, nitrogen, oxygen and sulfur;
Rh is selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphine;
the substituent group IIIB is selected from any one of IIIB-a to IIIB-j; 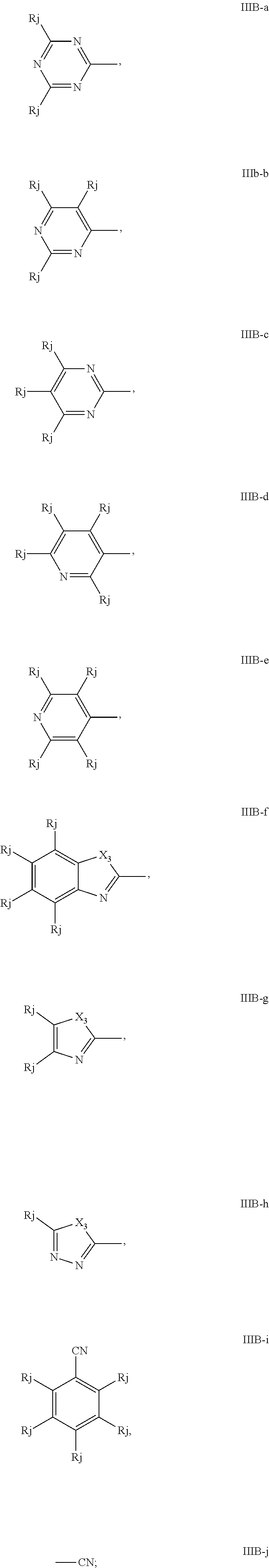
X₃ is selected from oxygen and sulfur; and
Rj is selected from any one of hydrogen, deuterium, halogen, nitrile, substituted or unsubstituted alkyl, substituted or unsubstituted haloalkyl, substituted or unsubstituted alkoxy, substituted or unsubstituted haloalkoxy, substituted or unsubstituted aryl, substituted or unsubstituted haloaryl group, substituted or unsubstituted silyl group, and substituted or unsubstituted heterocycle.

17. The light-emitting device according to claim 16, wherein a mass proportion of the second host material in the light-emitting layer is greater than or equal to 20% and less than or equal to 55%.

18. The light-emitting device according to claim 3, wherein a mass proportion of the second host material in the light-emitting layer is less than or equal to a mass proportion of the first host material in the light-emitting layer.

19. The light-emitting device according to claim 1, wherein a light-emitting unit includes a plurality of light-emitting layers, and the plurality of light-emitting layers are stacked in the first direction.

20. A display panel, comprising the light-emitting device according to claim 1; and
further comprising a driving circuit, wherein the driving circuit is configured to drive the light-emitting device to emit light.

21. A display apparatus, comprising the display panel according to claim 20; and
further comprising a driver chip, wherein the driver chip is configured to drive the display panel to perform display.
